(19) United States
(12) Patent Application Publication
(10) Pub. No.: US 2024/0159912 A1
(43) Pub. Date: May 16, 2024

(54) METHOD AND APPARATUS FOR DETERMINING A FREQUENCY RELATED PARAMETER OF A FREQUENCY SOURCE USING PREDICTIVE CONTROL

(71) Applicant: Focal Point Positioning Limited, Cambridge (GB)

(72) Inventors: Ramsey Michael FARAGHER, Cambridge (GB); Robert Mark Crockett, Cambridge (GB); Peter James Duffett-Smith, Cambridge (GB)

(21) Appl. No.: 18/388,703

(22) Filed: Nov. 10, 2023

Related U.S. Application Data
(60) Provisional application No. 63/424,185, filed on Nov. 10, 2022.

(51) Int. Cl. G01S 19/23; G01S 19/20

(52) U.S. Cl. CPC G01S 19/235; G01S 19/20; H03L 7/085

(57) ABSTRACT

A method, apparatus, and system for determining a frequency related parameter of a frequency source using predictive control includes receiving, at an antenna of the receiver, a plurality of signals from a plurality of remote source, generating motion compensated correlation results using a determined motion of the antenna of the receiver, the received plurality of signals, and a local signal derived from the local frequency source, using predictive control to predict the frequency related parameter of the local frequency source, phase compensating the motion compensated correlation results to produce phase compensated correlation results using a plurality of phasor sequences that are based on the predicted frequency related parameter of the local frequency source, and jointly analysing the phase compensated correlation results associated with the plurality of remote sources to determine a frequency offset of the local frequency source.

### CROSS-REFERENCE TO RELATED APPLICATIONS

This application claims the benefit of and priority to U.S. Provisional Patent Application Ser. No. 63/424,185, filed on Nov. 10, 2022, and PCT application No. PCT/GB2023/052056, filed on Aug. 3, 2023, which claims benefit of and priority to U.S. Provisional Patent Application Ser. No. 63/394667, filed on Aug. 3, 2022, which are all hereby incorporated by reference in their entireties.

### FIELD

Embodiments of the present principles generally relate to radio communications and, in particular, relate to a method, apparatus and system for determining, using predictive control, a frequency related parameter of a frequency source used by, for example, a radio receiver.

### BACKGROUND

Modern positioning and communications devices such as cellular phones have frequency sources (e.g., local oscillators) that can provide a frequency reference for a variety of different applications. Often cellular devices comprise relatively low-cost local oscillators, such as quartz oscillators. These low-cost oscillators can provide stable frequency references over short time periods. However, the frequency reference they produce can be unstable over longer time periods and can also be unstable when their operating conditions change. Examples of changing operating conditions include temperature, vibrations, and accelerating forces such as shocks when the device is jolted or dropped.

One application that can require a frequency reference from a local frequency source is GNSS positioning. Unlike many other applications associated with a cellular phone, however, GNSS positioning requires a very stable frequency reference. Such stable references can be costly and increase the cost of any device requiring a very stable frequency source.

Therefore, there is a need in the art for a method, apparatus and system for determining a frequency related parameter, such as errors or offsets in the phase, frequency, frequency rate or higher-order terms, of a local reference signal generated by an unstable frequency source within a receiver, such that the determined frequency related parameter can be used to improve the functionality of a positioning device or communications device that relies upon an unstable local frequency source.

### SUMMARY

Embodiments of the present invention generally relate to a method, apparatus and system for determining a frequency related parameter of a frequency source using predictive control as shown in and/or described in connection with at least one of the figures and the disclosure provided herein.

These and other features and advantages of the present disclosure can be appreciated from a review of the following detailed description of the present disclosure, along with the accompanying figures in which like reference numerals refer to like parts throughout.

### BRIEF DESCRIPTION OF THE DRAWINGS

Embodiments of the invention are now described, by way of example, with reference to the drawings, in which:

FIG. 1 depicts a high-level block diagram of a communication environment in which an embodiment of a receiver of the present principles can be applied in accordance with an embodiment of the present principles;

FIG. 2 depicts a high-level block diagram of a radio receiver in accordance with at least one embodiment of the present principles;

FIG. 3 depicts a high-level block diagram of a computing device suitable for use in a receiver of the present principles in accordance with at least one embodiment of the present principles;

FIGS. 4A and 4B, together, depict a flow diagram of a method of determining frequency error of a frequency source using predictive control in accordance with at least one embodiment of the present principles;

FIG. 5 depicts a graphical representation of a joint analyzation process used to calculate frequency error information in accordance with at least one embodiment of the present principles; and

FIG. 6 depicts a flow diagram of a method that can be executed by the prediction software of FIG. 3 in accordance with at least one embodiment of the present principles.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present principles include a method, apparatus and system for determining a frequency related parameter of a frequency source within a receiver to, for example, correct for inaccuracies of the frequency source. While the concepts of the present principles are susceptible to various modifications and alternative forms, specific embodiments thereof are shown by way of example in the drawings and are described in detail below. It should be understood that there is no intent to limit the concepts of the present principles to the particular forms disclosed. On the contrary, the intent is to cover all modifications, equivalents, and alternatives consistent with the present principles and the appended claims. For example, although embodiments of the present principles will be described primarily with respect to determining and, in some embodiments, correcting for inaccuracies of a local frequency source in positioning systems, embodiments in accordance with the present principles can be applied to substantially any system for determining a frequency parameter of a frequency source in accordance with the present principles.

Embodiments of the present principles include a method, apparatus, and system for determining a frequency related parameter of a frequency source within a receiver, which can include receiving a plurality of signals from a plurality of remote sources; generating motion compensated correlation results using a determined receiver motion, the received signals and a local signal derived from the frequency source; phase compensating the motion compensated correlation results to produce phase compensated correlation results using a plurality of phasor sequences that represent hypotheses of a frequency related parameter of the frequency source, where the range of hypotheses are constrained using one or more predictions of the frequency related parameter based upon, for example, receiver operation and/or environment; and jointly analysing the phase compensated correlation results associated with the plurality of remote sources to determine a frequency offset of the frequency source. The frequency offset can include, but is not limited to, errors or offsets in the phase, frequency, frequency rate or higher-order terms of the output of the frequency source that can be due to motion of the receiver/antenna.

In some embodiments, each phasor sequence in the plurality of phasor sequences can have a length that is defined by the expected stability of the local frequency source. If the local frequency source is stable over a period equal to or longer than a desired coherent integration period, then the length may be the same as the coherent integration interval. However, for unstable frequency sources, the phasor sequence length may be shortened such that multiple subinterval correlations may occur and a preferred phasor sequence in each subinterval used to produce the phase compensated correlation results.

As such, determined frequency error information can be used to facilitate use of a long coherent integration interval for signal reception and processing even in circumstances in which an unstable frequency source is being used. For example, frequency errors in each subinterval can be corrected such that the entire sequence is eventually corrected. Embodiments of the present principles enable coherent integration even if the underlying frequency source is not stable during the entire period (interval of the received signal) and advantageously improve the ability of, for example, a positioning system to determine a range to a GNSS satellite in a poor positioning environment in which the system includes a relatively unstable frequency source.

Some embodiments of the present principles for improving oscillator performance in a radio receiver process received signals (e.g., radio signals such as WiFi, global navigation satellite system (GNSS) signals, cellular telephone signals, and the like) to determine a frequency related parameter of the frequency source of a receiver of the present principles. In some embodiments, the frequency related parameter can include errors or offsets in a phase, frequency, frequency rate or higher-order terms, of the frequency source. The determined offset can be used to improve signal processing of received signals such that, for example, weak signals can be received that otherwise could not be received. By correcting for the frequency error in accordance with the present principles, the frequency source within the receiver does not have to be very accurate or be very robust to withstand environmental conditions. In some embodiments, the frequency error can include a frequency difference between a correct frequency needed to accurately receive signals and a current frequency of the frequency source. In some embodiments, the frequency error can also include a frequency rate which is the evolution of the frequency over time. Embodiments of the present principles can process received signals to facilitate removing local frequency errors such that the local frequency source is as accurate as an oscillator (e.g., an atomic clock in the case of GNSS signals) used in the transmitter of a remote signal source.

In some embodiments, to determine a frequency error of, for example a local frequency source of a receiver of the present principles, a motion of the receiver can be determined using, for example, inertial navigation techniques and the determined motion can be used to motion compensate received signals such that the transmitted signal or signals are accurately received. Further processing of the received signal(s) facilitates determining the frequency related parameter or parameters of the local frequency source. The parameter is then used by the receiver to improve processing of the received signals. As such, in accordance with the present principles, an inexpensive, unstable frequency source can be used in a receiver of the present principles and the receiver would still be able to accurately receive transmitted signals from remote signal sources.

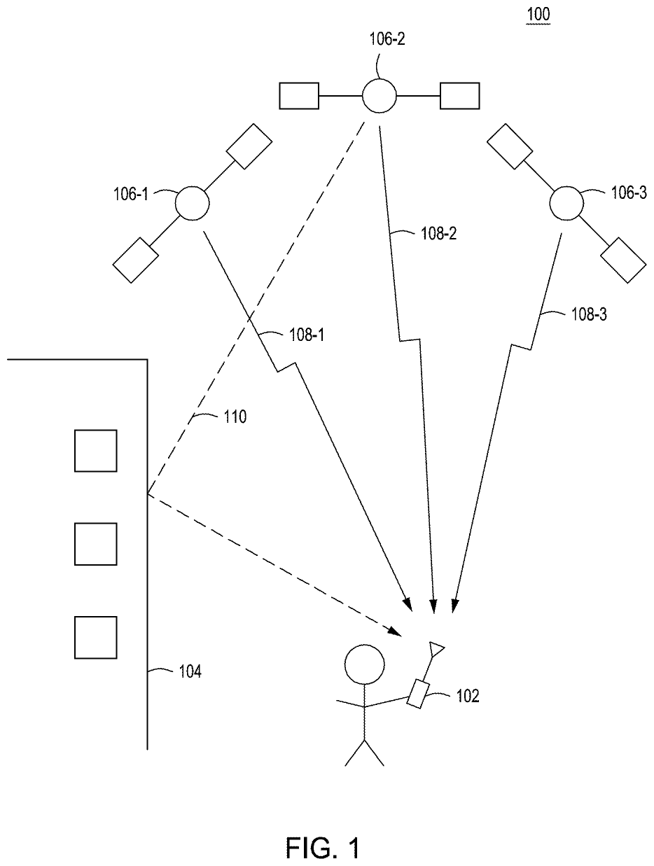

FIG. 1 depicts a high-level block diagram of a communication environment 100 in which an embodiment of a receiver of the present principles can be applied in accordance with an embodiment of the present principles. The communication environment 100 of FIG. 1 illustratively comprises three transmitters 106-1, 106-2 and 106-3 and a receiver 102 that utilizes frequency source operation improvement techniques in accordance with at least one embodiment of the present principles. In the embodiment of FIG. 1, the receiver 102 is a mobile device including, but not limited to at least one of a cellular telephone, a laptop computer, a tablet, an Internet of Things (IoT) device, and an embedded communication/navigation system in, for example, a vehicle. The transmitters 106-1, 106-2, 106-3 (collectively, transmitters 106) of the embodiment of FIG. 1 respectively transmit signals 108-1, 108-2, 108-3 (collectively, signals 108). The transmitters 106 of the present principles can include any form of transmitter capable of transmitting a deterministic code, for example, a Gold code, a Barker code, or some other form of repetitive acquisition code/reference frequency signal.

That is, many of today's radio communications systems utilize encoded digital signals to improve communication throughput and security. Most of these systems utilize some form of deterministic digital code (e.g., Gold codes or other forms of acquisition code) to facilitate signal acquisition. Such a digital code(s) is received by a receiver and broadcast by a signal source/transmitter to enable communications receivers to find, acquire and receive the transmitted signals. Using such deterministic codes combined with accurate motion information for the receiver, embodiments of the present principles are useful for identifying frequency related parameters, such as frequency errors, generated by local frequency sources within the receiver. A technique for determining frequency related parameters using receiver motion information in accordance with the present principles can include a SUPERCORRELATION™ technique which is described in commonly assigned U.S. Pat. No. 9,780,829, issued 3 Oct. 2017; U.S. Pat. No. 10,321,430, issued 11 Jun. 2019; U.S. Pat. No. 10,816,672, issued 27 Oct. 2020; US patent publication 2020/0264317, published 20 Aug. 2020; and US patent publication 2020/0319347, published 8 Oct. 2020, which are incorporated herein by reference in their entireties. Upon knowing the frequency related parameters, embodiments of the present principles can generate a frequency offset to correct for the error or otherwise use the known error to improve signal processing.

In some embodiments of the present principles, the transmitters 106 can comprise at least one of GNSS satellites, cellular telephone transmitters, WiFi transmitters, Bluetooth transmitters and the like, in which the transmitters 106 utilize a frequency source that is more accurate than the oscillator used in the receiver 102. In the embodiment of FIG. 1, the transmitters 106 illustratively comprise GNSS satellites, however, the transmitters 106, which can be referred to alternatively as remote reference/signal sources, can operate as part of any navigation system known in the art, for example a GNSS positioning system. In general, the reference sources can be comprised of any combination of satellite sources, terrestrial sources, or other types of reference sources.

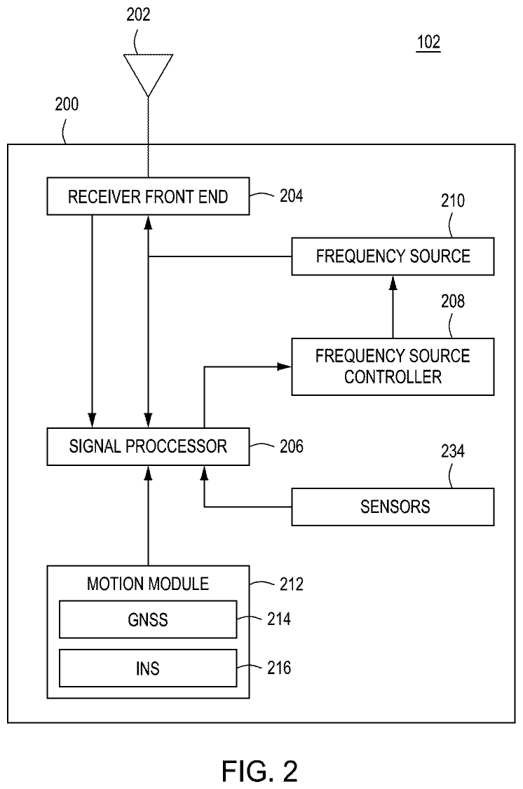

In the communication environment 100 of FIG. 1, the receiver 102 receives the signals 108 from the transmitters 106 and processes the signals in accordance with embodiments of the present principles to improve the operation of a local frequency source (described in greater detail with reference to FIG. 2) of the receiver 102.

In some embodiments, the receiver 102, via signal processing, can differentiate between direct signals 108 received (i.e., signals that propagate directly from the transmitter to the receiver, sometimes referred to as line-of-sight (LOS) signals) and indirect signals 110 (i.e., signals that are reflected from an object, sometimes referred to as non-line-of-sight (NLOS) signals) that reflect from structures proximate the receiver 102. In some embodiments, the receiver 102 can implement known satellite ephemeris or a transmitter map to determine which signals are likely to be direct signals. Alternatively or in addition, in some embodiments, the receiver 102 can differentiate direct and indirect signals using a SUPERCORRELATION™ technique as described in commonly assigned U.S. Pat. No. 9,780,829, issued 3 Oct. 2017; U.S. Pat. No. 10,321,430, issued 11 Jun. 2019; U.S. Pat. No. 10,816,672, issued 27 Oct. 2020; US patent publication 2020/0264317, published 20 Aug. 2020; and US patent publication 2020/0319347, published 8 Oct. 2020, which are hereby incorporated herein by reference in their entireties.

FIG. 2 depicts a high-level block diagram of a radio receiver 102 in accordance with at least one embodiment of the present principles. The receiver 102 of FIG. 2 illustratively comprises a mobile platform 200 and an antenna 202. In some embodiments, the receiver 102 can comprise a portion of a laptop computer, mobile phone, tablet computer, Internet of Things (IoT) device, unmanned aerial vehicle, mobile computing system in an autonomous vehicle or human operated vehicle, and the like. In general, embodiments of the present principles can be implemented in any environment in which a mobile receiver can be used and the receiver uses a frequency source, such as an oscillator.

Typically, the mobile platform 200 and the antenna 202 are an indivisible unit (e.g., mobile phone) where the antenna 202 moves with the mobile platform 200. The operation of the SUPERCORRELATION™ technique operates based upon the motion of the signal receiving antenna. As such, any mention of motion or receiver motion described herein refers to the motion of the antenna 202. In some embodiments, the antenna 202 can be separate from the mobile platform 200. In such embodiments, the motion estimate used in the motion compensated correlation process is the motion of the antenna 202. In most scenarios, the motion of the mobile platform 200 is the same as the motion of the antenna 202 and, as such, the following description will assume that the motion of the platform 200 and antenna 202 are the same.

In the embodiment of FIG. 2, the mobile platform 200 illustratively includes a receiver front end 204, a signal processor 206, frequency source controller 208, a frequency source 210, sensors 234 and a motion module 212. Although in the embodiment of FIG. 2, the signal processor 206 illustratively depicts a single processor, in some embodiments of the present principles, the signal processor of the present principles can comprise two or more processors. In the embodiment of FIG. 2, the receiver front end 204 down-converts, filters, and samples (digitizes) the received signals. The output of the receiver front end 204 is a digital signal containing data. In some embodiments, the data of interest can include a deterministic training or acquisition code (e.g., Gold code), which can be implemented by a transmitter/signal source to enable a receiver to synchronize the transmission to the receiver 102. The receiver 102 is configured to process signals received by the antenna 202 and can include any suitable components, such as an amplifier or an analogue to digital converter (not shown) to accomplish such processing.

In some embodiments of the present principles, the frequency source (e.g., a local oscillator) 210 is simple and low cost and can comprise a quartz oscillator. The frequency source 210 is configured to provide a timing signal for various applications performed by the receiver 102 (described in greater detail below).

In the embodiment of FIG. 2, the signal processor 206 processes signals (e.g., the digitized received signals) from the receiver front end 204. As depicted in the embodiment of FIG. 2, the signal processor 206 can further receive signals from the motion module 212 and the sensors 234. The signal processor 206 utilizes determined receiver motion information from the motion module 212 to perform motion compensated correlation. That is, the motion module 212 generates a motion estimate for movement of the receiver 102 using motion measurement devices such as gyroscopes, magnetometers, velocity measuring devices, step counting devices, and the like). In the embodiment of FIG. 2, the motion module 212 comprises an inertial navigation system (INS) 216 as well as a global navigation satellite system (GNSS) receiver 214 for receiving signals from one or more of GPS, GLONASS, GALILEO, BEIDOU satellites. In the embodiment of FIG. 2, the INS 216 device of the present principles can comprise one or more of, but not limited to, a gyroscope, a magnetometer, an accelerometer, and the like (i.e., conventional components used in an inertial measurement unit (IMU)).

In some embodiments, a motion of the receiver 102 (or, equivalently, the antenna 202 of the receiver 102) can be determined through measurement of the receiver motion using included motion measurement devices. Alternatively or in addition, the motion of the receiver 102 can be determined by assuming the receiver motion based upon past motion (e.g., constant motion in a particular direction due to travel in a vehicle or repetitive motion due to pedestrian travel). In addition, in some embodiments motion of a receiver can be extrapolated or computed from prior motion in specific environments. Machine learning techniques can be used in such situations to predict receiver motion.

To facilitate motion compensated correlation (described in greater detail below), the motion module 212 produces motion information (sometimes referred to as a motion model) comprising at least a velocity of the antenna 202 in the direction of a transmitter/emitter of interest (i.e., an estimated direction along a path of signal propagation from a source of a received signal). In some embodiments, the motion information can also include estimates of platform orientation or heading including, but not limited to, pitch, roll and yaw of the platform 200/antenna 202.

In accordance with the present principles, in embodiments of a receiver of the present principles in which the frequency source is somewhat stable over the coherent integration interval of the received signals, a frequency offset determined in accordance with the present principles can be communicated to the frequency source controller 208 in which a frequency control signal is created to control the frequency source 210 using information regarding the determined frequency offset to adjust the frequency source 210 in a closed loop manner. That is, the frequency source 210 provides timing signals to the signal processor 206 and the receiver front end 204 for use in received signal demodulation and processing. Alternatively or in addition, in some embodiments, the determined frequency offset can be stored in a memory for use by software applications or other components of a receiver of the present principles in an open loop manner.

In some embodiments in which the stability period of the frequency source 210 is substantially shorter than a desired coherence interval, the determined frequency related parameters are used by the signal processor 206 to process received signals and correlation results (buffered signals/results) to improve reception of signals.

More specifically, in a correlation process a local frequency reference provided by a local frequency source, such as the local frequency source 210 of FIG. 2, is used to generate a local signal that attempts to replicate a received positioning signal from a remote, more accurate signal source. The correlation process can include integrating these signals over longer periods of time to improve the result of the correlation. However, the local frequency reference from the local frequency source has to be stable over the integration period because the local signal is generated using the local frequency source. As such, any errors in the local frequency reference, for example, discrepancies with respect to a known or predictable frequency reference signal used to produce a positioning signal, propagate to the local signal. Thus, if the local frequency source 210 is not stable over the integration period, then the local signal will also not be stable over the integration period.

In accordance with the present principles, frequency changes of a local frequency source that occur over time can be predicted by, in some embodiments, monitoring the operational environment of a receiver of the present principles, such as the receiver 102 of FIG. 1. Referring back to FIG. 2, the sensors 234 can provide information regarding an operating environment of the receiver 102. For example, in some embodiments, the sensors 234 can provide information regarding at least temperature, shock (acceleration), component utilization indicator (an event sensor), and the like. In the embodiment of FIG. 2, the signal processor 206 can use the information from the sensors 234 to predict a frequency offset that results when, for example, a temperature changes in an environment in which the receiver 102 is operating, and/or when the receiver 102 is dropped and receives a shock, and/or when certain components of the receiver platform are activated, and any other event that can be sensed that effects a stability of a frequency of the frequency source 210 of the receiver 102. For example, certain components when activated can raise the temperature of the receiver 102 or can cause voltage or electronic noise fluctuations that can impact a frequency stability of the frequency source 210. By predicting frequency fluctuations in accordance with the present principles, any frequency offsets of the local frequency source can be compensated.

In some embodiments, the sensors 234 can include circuits and software configured to detect operational changes of the receiver 102. For example, techniques can be used to detect changes in operating parameters (event sensing) of the receiver 102 that can affect the frequency of the local frequency source 210 of the receiver 102, such as activation or deactivation of a GNSS receiver, changes in screen brightness, activation or deactivation of a wifi modem, activation or deactivation of a cellular modem, and the like.

In some embodiments of the present principles, a receiver of the present principles, such as the receiver 102 of FIGS. 1 and 2, can include a machine learning system (not show) that is trained to learn a model that associates an amount of change of a frequency-affecting parameter (e.g., a change in temperature and/or the activation/deactivation of a component of a receiver) with an amount of frequency change/fluctuation of, for example, a local frequency source (e.g., frequency source 210) of the receiver 102.

In some embodiments of the present principles, a machine learning system of the present principles, such as a machine learning system (not shown) of a receiver of the present principles, such as the receiver 102 of FIGS. 1 and 2, can include a multi-layer neural network comprising nodes that are trained to have specific weights and biases. In some embodiments, the machine learning system can employ artificial intelligence techniques or machine learning techniques to analyze frequency changes/errors in frequencies provided by local frequency sources due, for example, to specific changes in an environment or operating parameter of a receiver in which the local frequency source resides. In some embodiments in accordance with the present principles, suitable machine learning techniques can be applied to learn commonalities in sequential application programs and for determining from the machine learning techniques at what level sequential application programs can be canonicalized. In some embodiments, machine learning techniques that can be applied to learn commonalities in sequential application programs can include, but are not limited to, regression methods, ensemble methods, or neural networks and deep learning such as ‘Seq2Seq’ Recurrent Neural Network (RNNs)/Long Short-Term Memory (LSTM) networks, Convolution Neural Networks (CNNs), graph neural networks applied to the abstract syntax trees corresponding to the sequential program application, and the like. In some embodiments a supervised machine learning (ML) classifier/algorithm could be used such as, but not limited to, Multilayer Perceptron, Random Forest, Naive Bayes, Support Vector Machine, Logistic Regression and the like. In addition, in some embodiments, the ML classifier/algorithm of the present principles can implement at least one of a sliding window or sequence-based techniques to analyze data content.

A machine learning system (not shown) of a receiver of the present principles, such as the receiver 102 of FIGS. 1 and 2, can be trained using a plurality (e.g., hundreds, thousands, millions, etc.) of instances of pairs of data in which the training data comprises a plurality of data pairs that associate a measured amount of change/error in a frequency of a local frequency source with specific changes in an environment or operating parameter of a receiver to train a machine learning system of the present principles to recognize/identify/determine an effect on a frequency output of a local frequency source due to a change in at least one of an environment or operating parameter of a receiver in which the local frequency source resides.

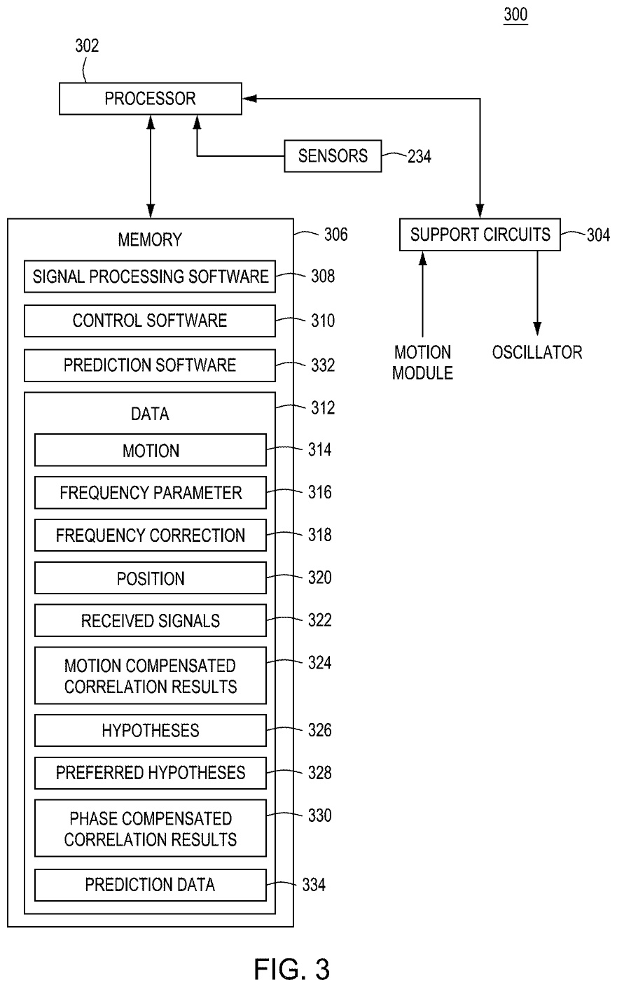

Alternatively or in addition, in some embodiments a look-up table can be stored in a memory (e.g., a memory depicted in FIG. 3) accessible to a receiver of the present principles, the look-up table including at least an association between a measured amount of change/error in a frequency of a local frequency source due to specific changes in an environmental parameter and/or operating parameter of a receiver. In some embodiments, a look-up table or machine learning model of the present principles can be multi-dimensional to accommodate multiple events occurring simultaneously which cause a change in a frequency parameter of a local frequency source. In accordance with the present principles, such models can be used to predict a frequency parameter change upon the occurrence of one or more sensed events.

Referring back to FIG. 2, in accordance with the present principles, information from the sensors 234 and/or the look-up table/models can be used to control operational functions of the receiver to constrain parameters. For example, if a sensor 234 indicates that a temperature in which a receiver is operating is becoming extreme to the point of making phase compensation a non-viable option to correct for the temperature, the signal processor 206 can inform the receiver to perform a mitigating action to lower the temperature (e.g., deactivate the screen, slow the processor speed, deactivate one or more modems, etc.). In general, the sensors 234 are configured to measure operational and/or environmental attributes affecting/impacting the receiver that cause changes in a frequency related parameter (e.g., the local frequency source frequency error). The sensors 234 can include, but are not limited to, at least one temperature sensor, at least one accelerometer (i.e., for measuring shock to the receiver), at least one indicator of computing device component activation, at least one indicator of a platform component activation (e.g., WiFi radio, cellular radio, screen settings) and the like.

With reference back to FIGS. 1 and 2, in operation, the receiver 102 can receive a plurality of transmitter signals (signals from known remote sources). The signal processor 206 can use a determined motion of the receiver 102 to perform motion compensated correlation (e.g., a SUPERCORRELATION™ technique) of the received signals to derive at least one frequency related parameter (e.g., frequency/phase error). The receiver 102 can use the at least one frequency related parameter to cause a controller to communicate a signal to a local frequency source to adjust a frequency of the frequency source to improve processing of currently received signals and, in some embodiments, can improve reception of subsequently received signals. For example, in one embodiment, the frequency source controller 208 uses a determined frequency error to produce a frequency correction for the frequency source 210 such that subsequently received signals can be more accurately received. In other embodiments, the signal processor 206 can continuously correct the frequency error of currently received signals' correlation results such that an unstable frequency source can be used for long periods of coherent integration.

For example, embodiments of the present principles can be implemented as a GNSS signal receiver to receive a plurality of GNSS satellite transmissions. Within the receiver, a reference frequency in the received signals can be correlated with locally generated frequency signals to produce correlation results. The receiver can then use an inertial navigation system (INS) to determine the motion of the receiver and this motion can be used to motion compensate at least one of the received signal, local signal and/or correlation results to produce motion compensated correlation results. The determined receiver motion can be used to generate phasor sequences for adjusting signal phase that can applied to the received signals, the local signals or the correlation results to phase compensate the correlation results to compensate for receiver motion.

That is, after the correlation results are motion compensated, embodiments of the present principles can then apply phase compensation to the motion compensated correlation results. The phase compensation utilizes a phasor sequence that represents the frequency related parameter. The phasor sequences are applied to the correlation results as hypotheses to be tested to identify a best or optimal hypothesis as a preferred hypothesis. If the frequency source is only stable for periods that are less than the desired coherent integration interval, then the hypotheses are short phasor sequences having a length of only a subset of motion compensated correlation results. The preferred hypotheses of each subset are concatenated to form a phasor sequence having a length of the desired coherent integration interval.

In accordance with the present principles, the phasor sequence hypotheses can be constrained using a predictive technique of the present principles that creates stability/error predictions for a local frequency source based upon a sensing of frequency-affecting parameters of a receiver operation (e.g., screen is on creating heat that typically alters the frequency related parameter in a predictable manner), receiver environment (e.g., external temperature, shock caused by the receiver being dropped), or both operation and environment. The predictions can be used to control a size and density of a search space for the hypotheses (i.e., the range and number of hypotheses) as well as control the length of the subsets of motion compensated correlation results. For example, if the receiver temperature is rising and such a rise is known to cause the frequency related parameter of a local frequency source to change, the length of the phasor sequence hypotheses subsets can be shortened. In addition, if the direction and amount of changes is predicted, the hypotheses phasor values can be centered around the predicted frequency related parameter such that a preferred hypothesis can be rapidly determined. The prediction of the present principles can be generated in real time or the prediction can be accessed from a database (e.g., look-up table) that was previously produced using, for example, empirical data.

In some embodiments, by combining the correlation results from received signals of multiple transmitters and analyzing the combined (joint) results, the remaining correlation error can be determined as a common error to all the satellite signals and is a function of the receiver frequency parameter(s). A receiver of the present principles can then generate a sequence of frequency offsets (a model) and can use the model to process the received signals or otherwise to improve receiver function. In addition to GNSS receivers, such frequency source improvements of the present principles are useful in mobile devices that utilize communications techniques that use a deterministic code, for example, but not limited to, WiFi, Bluetooth, cellular telephone, and the like.

Alternatively or in addition, in some embodiments of the present principles a predictive pattern (e.g., changes in the frequency related parameter(s) over time) can be determined. Consequently, the predictions of the present principles can extend into the future to correct for future frequency errors of, for example, a local frequency source in accordance with the present principles.

FIG. 3 depicts a high-level block diagram of a computing device 300 suitable for use in a receiver of the present principles, such as the receiver 102 of FIGS. 1 and 2. For example, in some embodiments, the computing device 300 can be implemented for performing the function of the signal processor 206 and/or the frequency source controller 208 of the embodiment of the receiver 102 FIG. 2 in accordance with at least one embodiment of the present principles. The computing device 300 of FIG. 3 illustratively comprises at least one processor 302, support circuits 304, and a memory 306. The at least one processor 302 can be any form of processor or combination of processors including, but not limited to, central processing units, microprocessors, microcontrollers, field programmable gate arrays, graphics processing units, digital signal processors, and the like. The support circuits 304 can comprise well-known circuits and devices facilitating functionality of the processor(s). The support circuits 304 can comprise one or more of, or a combination of, power supplies, clock circuits, analog to digital converters, communications circuits, cache, drivers, and/or the like. As depicted in FIGS. 2 and 3, the processor 302 can receive signals from the sensors 234, which are configured to measure operational and/or environmental attributes impacting the receiver that cause changes in a frequency related parameter (e.g., the frequency source frequency error).

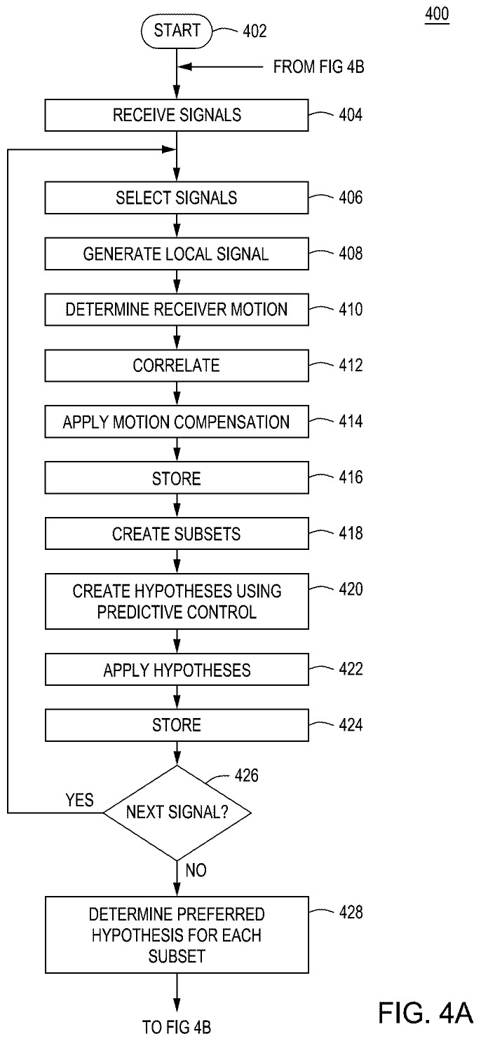

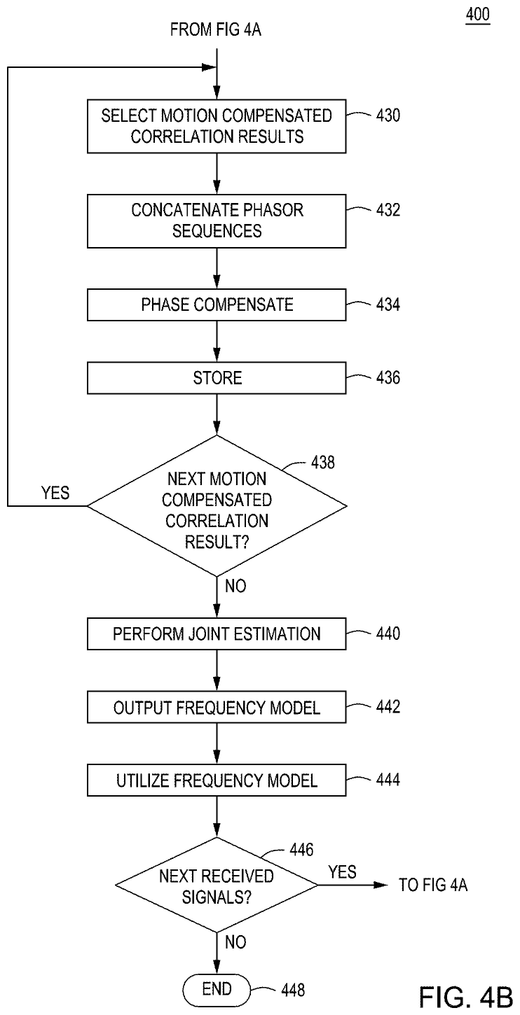

In the embodiment of FIG. 3, the memory 306 can include one or more forms of non-transitory computer readable media including one or more of, or any combination of, read-only memory or random-access memory. The memory 306 can store software and data including, for example, signal processing software 308, control software 310 and data 312. The signal processing software 308, when executed by the one or more processors 302, can perform motion compensated correlation (the motion compensated correlation process is described in greater detail below with respect to FIG. 4) upon the received signals to estimate the frequency source frequency error (e.g., phase, frequency, frequency rate or higher-order terms). The signal processing software 308 can include prediction software 332 that, when executed, predicts the frequency source frequency error in view of signals from the sensors 234 or other information such as activation or deactivation of various computing device or platform components. In some embodiments, the operation of the signal processing software 308 and the control software 310 can respectively function within the signal processor 206/302 and frequency source controller 208.

In various embodiments, the data 312 stored in the memory 306 can also include information regarding prediction data 334, receiver motion 314, a frequency related parameter 316, frequency correction data 318, position data 320, receiver signals 322, motion compensated correlation results 324, phasor hypotheses 326, preferred hypotheses 328, and phase compensated correlation results 330 as well as data used in signal processing, such as signal estimates, correlation results, motion compensation information, and the like.

As described herein, in some embodiments the signal processing software 308 can implement a SUPERCORRELATION™ technique as described in commonly assigned U.S. Pat. No. 9,780,829, issued 3 Oct. 2017; U.S. Pat. No. 10,321,430, issued 11 Jun. 2019; U.S. Pat. No. 10,816,672, issued 27 Oct. 2020; US patent publication 2020/0264317, published 20 Aug. 2020; and US patent publication 2020/0319347, published 8 Oct. 2020, which are hereby incorporated herein by reference in their entireties, to determine at least one frequency related parameter. The motion information 314 from the motion module 212 in FIG. 2 can be used to perform motion compensated correlation on the received signals 322 to produce motion compensated correlation results. From the motion compensated correlation process, the signal processing software 308 can estimate at least one frequency related parameter (e.g., frequency error or offset) and, in some embodiments, the control software 310 produces a frequency correction to be applied to a local frequency source 210 or to a frequency signal from the local frequency source 210. Alternatively or in addition, the at least one frequency related parameter can be used in the digital processing of the received signals to improve signal processing.

As described herein, embodiments of the present principles can use motion estimation to motion compensate signals received from each transmitter along the direction of signal propagation from the transmitter to the receiver such that remaining phase errors are substantially due to a local frequency source error contribution to each received signal. By knowing the local source frequency error, a frequency error offset or correction value can be applied to compensate for the error to enable a creation of a more accurate frequency that can be used in a signal correlation process of the present principles. Alternatively or in addition, a frequency error compensation signal can be applied as a phasor to the motion compensated correlation results to produce very accurate phase compensated correlation results. In some embodiments, the phase compensated correlation results can be used by, for example, a GNSS receiver for position location calculations. As such, by using a frequency correction technique of the present principles, a lesser quality frequency source in which a frequency significantly drifts in view of temperature changes, vibration, physical shock, power supply variation, etc., can be used in a receiver of the present principles. For example, rather than use a temperature compensated crystal oscillator (TCXO), embodiments of the present principles described herein enables the use of a less accurate, and low cost, voltage-controlled crystal oscillator (VCXO) or temperature-sensing crystal (TSX).

Embodiments of the present principles can be described as performing three subprocesses: 1) use the motion of the receiver to motion compensate correlation results from a correlation of an interval of reference frequencies of received signals with frequencies of local signals to produce a set of motion compensated correlation results; 2) perform phase compensation using subsets of the motion compensated correlation results and subinterval phasor sequences; and 3) perform full coherent integration interval phase compensation using concatenated subintervals of phasor sequences identified in subprocess 2). The resulting correlation results are motion compensated for receiver motion and are adjusted for any frequency source errors across the entire coherent integration interval. Consequently, a receiver of the present principles can accurately correlate the received signals over a long coherent integration interval even if the frequency source has significant errors across the interval.

FIGS. 4A and 4B depict a flow diagram of a method 400 for determining frequency related errors produced by a frequency source within a receiver using predictive control of FIGS. 1 and 2 in accordance with at least one embodiment of the present principles. Each block of the flow diagram can represent a module of code to execute and/or combinations of hardware and/or software configured to perform one or more processes described herein. Though described herein and illustrated in the figures in a particular order, the steps of the method 400 are not meant to be so limiting. Any number of blocks in the method 400 of the present principles can proceed in any order (including being omitted) and/or substantially simultaneously (i.e., within technical tolerances of processors, etc.) to perform the operations of embodiments of the present principles described herein.

The method 400 begins at 402 and can proceed to 404 where signals are received from a plurality of remote sources, such as, for example, GNSS satellites. The received signals are typically buffered for use in subsequent repetitive processing. The signals are received over a predefined interval (i.e., the desired coherent integration period). Each received signal comprises a synchronization or acquisition code, for example a Gold code, extracted from the radio frequency (RF) signal received at the antenna of a receiver of the present principles. The RF signal is down-converted, sampled and the digital code is extracted. The method 400 can proceed to 406.

At 406, one of the received signals is selected for processing. That is, in accordance with the present principles, a received signal from a particular satellite is selected from the plurality of signals received by a receiver of the present principles from the plurality of satellites. Although the following description of the method 400 describes sequentially processing each received signal of the plurality of received signals, in some embodiments, all the received signals can be processed in parallel. The method 400 can proceed to 408.

At 408, a local frequency signal is generated using the local frequency source of a receiver of the present principles as a local frequency reference signal. The local signal includes a locally generated code which matches the expected code encoded in the received signal. The method 400 can proceed to 410.

At 410, motion information for the receiver (or an antenna of the receiver) is determined. In some embodiments, motion information can be received from the motion determination module 212 of FIG. 2. The motion information can include an estimate of the motion of the receiver 100 of FIG. 1, for example one or more of velocity, heading, orientation, etc. In some embodiments, pertinent motion information includes at least the component of receiver motion (antenna motion) along the direct propagation path between the receiver and the remote source (e.g., satellite). The motion in the direction of the remote source causes a Doppler frequency variation in the received signal. Removing the effect of the motion significantly improves the reception and/or processing of the received signals. The method can proceed to 412.

At 412, the local signal is correlated with the selected received signal to produce a first correlation result. In one embodiment for receiving GNSS signals, the correlation periods can be 5 ms and result in 200 correlation peaks over a 1 second period (i.e., the desired coherent integration interval). The correlation results are complex values containing in-phase (I) and quadrature (Q) components. The method 400 can proceed to 414.

At 414, the selected received signal is motion compensated to form motion compensated correlation results. In one embodiment, the motion compensation technique used is the SUPERCORRELATION technique referenced above which applies a phasor sequence (i.e., a sequence of phase offsets applied to each complex valued correlation result). In some embodiments, the phasor sequence can be applied to the received signal, local signal, correlation results, or a combination of those signals to produce motion compensated correlation results. The method can proceed to 416.

At 416, the motion compensated correlation results can be stored. The motion compensated correlation results over the desired coherent integration period form a set of results, for example, 200 motion compensation correlation results in a 1 second coherent integration interval. The method 400 can proceed to 418.

At 418, the set of motion-compensated correlation results are divided into a sequence of subsets. In one embodiment, a 1 second interval can be divided into five 0.2 second subintervals. For example, a set of 200 results can be divided into subsets of 40 results. In general, in accordance with embodiments of the present principles, the set of motion-compensated correlation results can be divided into N subsets, where N is an integer. The number of results in a subset can be defined by an estimated stability period of the local frequency source of a receiver of the present principles. In some embodiments, N is predefined and fixed. In other embodiments, N can be variable based on, for example, measurements of the stability of the frequency source such that the number of subsets change as the stability of the frequency source changes as described in detail below. Other measurements that can be used to set the value of N include, but are not limited to, temperature, acceleration, and the status of other modules/components associated with a receiver of the present principles, such as processors, and WiFi and cellular transceivers. In some embodiments, the subsets can overlap. For example, each subset of 40 results can include a number of results, for example, 20 results, from an adjacent subset. In some embodiments, the length of the subsets can vary within an interval. Alternatively or in addition, the length and number of subsets can be defined by the prediction data 334 of the memory 306 of the computing device 300 of FIG. 3. The prediction data can reflect that the frequency offset is being tracked very accurately such that the length of the subsets can be lengthened or the number of subsets can be increased to increase the coherence interval. The method 400 can proceed to 420.

At 420, a plurality of phasor sequence hypotheses related to a frequency-related parameter of the frequency source are generated. In some embodiments, the hypotheses can be created using predictive control to limit the search space covered by the hypotheses. The frequency-related parameter can include a frequency offset, in which the frequency offset includes an error between the current frequency of the local frequency source of a receive and the true frequency needed to maximize the correlation value of the received signal (e.g., the GNSS satellite atomic clock frequency). Alternatively or in addition, the frequency-related parameter can be a frequency offset and a frequency rate offset, in which the frequency rate is a slope of the change in frequency over time and the frequency rate offset is the error in the rate. Each phasor sequence hypothesis comprises a time series of phase offset estimates that vary with the frequency-related parameters of the frequency source. A group of hypotheses are created for each subset of motion compensated correlation results. In some embodiments, the number of hypotheses used is controlled based on the prediction data.

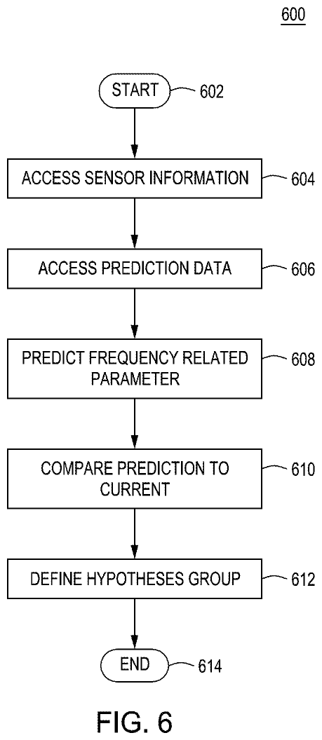

In some embodiments, the prediction software 232 of FIG. 2 uses information from the sensors 234 and the prediction data to define a size of the group of hypotheses to be used to optimize the correlation results. The operation of the prediction software is further described below with respect to FIG. 6. The method 400 can proceed to 422.

At 422, for the motion compensated correlation results of each received signal, a group of frequency-related hypotheses containing estimates of the phase offset sequences can be used to phase compensate the motion compensated correlation results over the subset (e.g., 40 motion compensated correlation results) in order to maximize the coherently-integrated correlation result over the subset, wherein the coherently-integrated correlation result is the summation of the phase-compensated correlation results. In accordance with the present principles, there is a group of frequency-related hypotheses representing a search space for each subset of motion compensated correlation results. That is, at 422, phase compensation is applied to each of the N subsets of motion compensated correlation results. The hypotheses are used as parameters to form a plurality of phase-compensated phasors to phase compensate the motion compensated correlation results. For each subset, a search is performed over frequency and frequency rate (i.e., a search using B frequency hypotheses and C frequency rate hypotheses) to determine the “best fit” frequency and frequency rate hypothesis for each subset. The application of each hypothesis results in a phase-compensated correlation result for a given subset of motion compensated correlation results. As such, for each subset, the search space has B×C hypotheses that produce B×C phase compensated correlation results for each of the N subsets. The method 400 can proceed to 424.

At 424, the subsets of phase compensated correlation results are stored. The method 400 can proceed to 426.

At 426, it is determined whether a next received signal is to be processed. For example, in some embodiments, the next received signal can be a signal received from a different signal source (e.g., different satellite) in the same time period as a prior processed signal. For a given time interval, there are X number of received signals from X different transmission sources (e.g., satellites 106-1, 106-2, 106-3 of FIG. 1). If the query is affirmatively answered, the method 400 can return to 406 to select the next received signal to process. If the query is negatively answered (i.e., all received signals in the current time instant have been processed), the method 400 can proceed to 428.

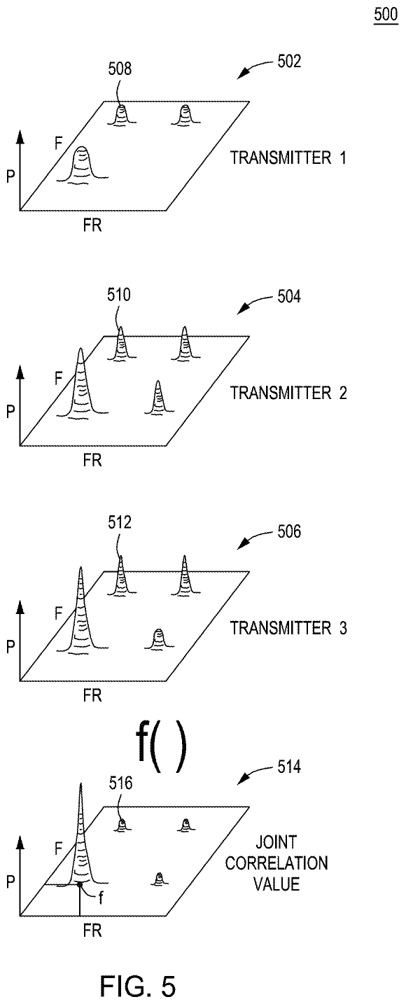

At 428, joint estimation is performed such that the phase compensated correlation results are combined (e.g., summed) to determine the hypotheses that maximize the correlation value of the phase compensated correlation results. The joint estimation process is described in greater detail below with reference to FIG. 5. In accordance with the present principles, for each subset, a frequency and frequency rate preferred hypothesis can be determined. The method 400 can proceed to 428.

At 428, a preferred hypothesis is determined for each of the subintervals using a joint correlation technique. That is, a joint correlation output (e.g., summation, weighted summation, or other function) is produced for each subinterval as a function of the plurality of phase compensated correlation results resulting from all the hypotheses and received signals. The joint correlation output can be a single value or a plurality of values that represent the parameters that provide an optimal or best phase compensated correlation output. The joint correlation output contains estimates of the frequency-related parameters. That is, all received signals have different receiver motion compensation because the receiver is moving differently with respect to each remote source, but all the received signals are processed with the same, common frequency error that can be found, for example, by stacking (summing) the plurality of correlation results associated with each subinterval and finding a common joint correlation value. The result can be the global maximum or a local maximum depending on the cost function implemented in combining the signals into a joint estimator. In some embodiments, such functions can include a simple summation, or a weighted summation using satellite elevation or another metric for the weightings. As such, embodiments of the present principles can determine the frequency and frequency rate values for each of the subset hypotheses that generate a joint correlation value having, for example, the largest magnitude or meets some other sufficiency criteria.

FIG. 5 depicts a graphical representation of a joint analyzation process 500 used to calculate frequency error information in accordance with at least one embodiment of the present principles, for example at 428 of the method 400. In the embodiment of FIG. 5, the phase compensated correlation results for transmitter 1 determined in accordance with the present principles are shown at 502, for transmitter 2 at 504 and for transmitter 3 at 506. Each plot in FIG. 5 is a three-dimensional representation of the frequency (F) and frequency rate (FR) search space and the power (P) in the correlation values. Each transmitter has a peak correlation value, respectively 508, 510 and 512 at a particular frequency and frequency rate. The summation of all the results is shown as plot 514 and forms the joint correlation output in accordance with an embodiment of the present principles. The joint correlation output contains estimates of various system parameters, and different functions applied to it can be used to recover system parameters. For example, the LOS components from each signal all accumulate within a common bin within the search space, revealing the local oscillator frequency and frequency rate offset for that epoch. The offsets from this “calibration point” to other bins in the search space containing non-insignificant power can be used to determine the azimuth and elevation from which the NLOS signals arrive. The frequency and frequency rate at the location of the joint correlation value are used to compensate for the frequency error of the local frequency source. All received signals can have different receiver motion compensation because the receiver can be moving differently with respect to each transmitter, but all the received signals are processed with the same, common frequency error that can be found by stacking (summing) the plurality of correlation values associated with each transmitter and finding a common joint correlation value. In some embodiments, the common joint correlation value can be the global maximum or a local maximum depending on the cost function implemented in combining the signals into a joint estimator. Example functions can include a simple summation, or a weighted summation using satellite elevation or another metric for the weightings. As such, the frequency and frequency rate values of the hypotheses that generate a joint correlation value having the largest magnitude can be determined.

In other embodiments, rather than using the largest magnitude correlation value, other test criteria can be used. For example, in some embodiments the method 400 of

FIG. 4 can further include monitoring the progression of correlations as hypotheses are tested and applying a cost function that indicates the best hypotheses when the cost function reaches a minimum (e.g., a small hamming distance amongst peaks in the correlation plots). In such embodiments, the joint correlation output that indicates the preferred hypothesis to be used for each subinterval can be a joint correlation value or a group of values. For each subinterval, there is a preferred hypothesis matrix representing an optimal phasor sequence to apply to a given subinterval of motion compensated correlation results.

Referring back to FIGS. 4A and 4B, at 430 of the method 400, one of the sets of motion compensated correlation results (i.e., from one of the remote sources) that were temporarily stored at 416 is selected. Although the motion compensated correlation results are described as being processed sequentially, in some embodiments the motion compensated correlation results can be processed in parallel. The method 400 can proceed to 432.

At 432, the subset phasor sequences from each preferred hypothesis are concatenated and smoothed (e.g., using a polynomial best fit or similar expression) to create a frequency/frequency rate model that extends over the entire coherent integration interval (e.g., 1 second).

At 434, the motion compensated correlation results are phase compensated by applying the interval length frequency-frequency rate model to the motion compensated correlation results. In some embodiments, the frequency-frequency rate model is used to adjust the phase of each complex valued correlation result. Each phase offset in the model is applied to a corresponding complex sample in the motion compensated correlation result. The method 400 can proceed to 436.

At 436, the phase compensated correlation results for the entire interval are temporarily stored for subsequent use. The method 400 can proceed to 438.

At step 438, it is determined whether a next set of correlation results for a different received signal are to be processed. If the query is affirmatively answered, the method 400 returns to 430 to select the next set of motion compensated correlation results to process. If the query is negatively answered (i.e., all motion compensated received signals have been processed), the method 400 proceeds to 440.

At 440, the phase compensated correlation results associated with all the received signals are jointly analyzed to determine a final frequency and/or frequency rate error model for the entire coherent integration interval. A joint correlation output is produced for the interval as a function (e.g., summation) of the plurality of phase compensated correlation values resulting from the concatenated preferred hypotheses and the motion compensated correlation results for each received signal. The joint correlation output can be a single value or a plurality of values that represent the parameters that provide an optimal or best correlation output. In some embodiments, the joint correlation output contains estimates of frequency related parameters such as a frequency offset of at least the local frequency source of the receiver due to receiver/antenna motion.

As described above, all received signals can have different receiver motion compensation because the receiver can be moving differently with respect to each transmitter, but all the received signals are processed with the same, common frequency error that can be found by stacking (summing) the plurality of phase compensated correlation values associated with a given interval of received signal and finding a common joint correlation value. In some embodiments this can be the global maximum or a local maximum depending on the cost function employed in combining the signals into the joint estimator. Example functions include a simple summation, or a weighted summation using satellite elevation or another metric for the weightings. As such, the frequency and frequency rate values of the interval hypothesis (concatenated subinterval hypotheses) that generate a joint correlation value having the largest magnitude can be determined.

As described above, in other embodiments, rather than using the largest magnitude correlation value, other test criteria can be used. For example, the progression of correlations across all received signals can be monitored and a cost function can be applied that indicates the common frequency and frequency rate error when the cost function reaches a minimum (e.g., a small hamming distance amongst peaks in the correlation plots). As such, the joint correlation output can be a joint correlation value or a group of values. The method 400 can proceed to 442.

At 442, the frequency and frequency rate error of the local frequency source, for example the difference between the hypothesised frequency and the local source frequency, are output. In one embodiment, interpolation is performed over the, for example, 200 frequency/frequency rate samples and a frequency model is produced for the frequency source over the coherent integration period. The method 400 can proceed to 444.

At 444, the frequency model is used. That is, in one embodiment, the frequency model can be used, for example, by a controller (e.g., controller 208) and/or a navigation engine (not shown) to correct frequency and receiver motion induced errors in the positioning solution. That is, in some embodiments, the frequency model of the present principles, can determine/reflect frequency errors induced in a frequency source of a local frequency source of a receiver that include frequency errors caused by at least one of receiver motion and changing receiver parameters (e.g., temperature changes, shock to the receiver, receiver equipment being turned on or off). In such embodiments, a controller of the present principle, such as controller 208 of the receive 102 of FIG. 2, can use the frequency errors, in some embodiments reflected by the determined frequency model, to determine a frequency offset to be applied to a frequency of the local frequency source 210 of the receiver 102 to correct for any determined frequency errors in the local frequency source 210. In some embodiments, the controller 208 applies the determined frequency offset to the frequency of the local frequency source 210 of the receiver 102 such that an integration period during which the local frequency source 210 of the receiver 102 is stable is extended.

Alternatively or in addition, in some embodiments the model and/or the discrete frequency/frequency rate samples are used for other purposes such as modelling the local frequency source in view of environmental changes (e.g., temperature, physical shock, received component activation and the like). Consequently, embodiments of the present principles can predict changes in the frequency and frequency rate as a result of environmental changes. The method can proceed to 446.

At 446, it is determined whether next received signals in a subsequent coherent integration period are to be processed. If the query is affirmatively answered, the method 400 can return to 404 of FIG. 4A. If the query is negatively answered, the method 400 ends at 448.

Embodiments of the present principles can be implemented to decrease the cost (i.e., bill of materials (BOM)) of a receiver of the present principles. As described above, a receiver with an unstable frequency source (e.g., low-cost oscillator) which uses embodiments of the present principles can be used to accurately receive positioning and/or communications signals over long coherent integration periods.

In some embodiments of the present principles, the number of sub-intervals, N, the length of the subsets and/or the number of hypotheses can be varied based upon the measured or predicted stability of the oscillator in view of environmental or functional conditions of the receiver.

FIG. 6 depicts a flow diagram of a method 600 that can be executed by the prediction software 332 of FIG. 3 in accordance with at least one embodiment of the present principles. In one embodiment, the method 600 can operate as a subroutine that can be executed with the method 400 of FIG. 4 to support the process of defining a group of hypotheses to be used with the plurality of phasor sequences.

The method 600 begins at 602 and proceeds to 604, where sensor information (e.g., temperature, shock, etc.) is accessed. In general, the sensor information can include any measurable value or event that impacts the frequency or the rate of drift of the frequency produced by the local frequency source of a receiver of the present principles. The method 600 can proceed to 606.

At 606, the prediction data is accessed. In one embodiment, the prediction data can include empirically determined frequency value or a frequency drift rate. The method 600 can proceed to 608.

At 608, the frequency related parameter (e.g., phase, frequency, frequency rate or higher-order terms) is predicted based on at least one the sensor information and prediction data. In one embodiment, the prediction is produced using a look-up table or other form of accessible database. In another embodiment, the prediction is produced in real time using a calculation or machine learning model as described above. In any of these embodiments, at 608, a prediction is generated of what the frequency related parameter should be based on the current environment surrounding or involving the platform and/or the operational state of the platform. The method 600 can proceed to 610.

At 610, the prediction is compared to the current value of the frequency related parameter and, at 612, the hypotheses group is defined. In one embodiment, the size of the difference between the prediction and the current value defines the size of the hypotheses group. For example, if the prediction and current values are very different, the number of hypotheses can be expanded. Conversely, if the difference is small, a fewer number of hypotheses can be used.

In other embodiments, the comparison can be used to adjust the centroid of the hypotheses group. For example, if the sensor information indicates that the receiver platform was dropped and the frequency is expected to jump to a different value in view of the shock, the center of the group of hypotheses can be positioned at the predicted frequency and the current frequency value can be ignored. As such, depending upon the environmental or operational occurrence, the group of hypotheses can be biased toward or away from the predicted or current values. The group of hypotheses comprises not only the total number of hypotheses, but also the number of subsets and the length of the subsets of phasors. Thus, at 612, the total number of hypotheses (i.e., the size and density of the search space), the number of subsets and the length of the subsets are defined. Alternatively or in addition, a prediction pattern can be produced over time for the frequency related pattern. The method 600 can proceed to 614.

At 614, the method 600 ends and returns to 422 in FIG. 4A to apply the determined group of hypotheses.

In some embodiments, a method for determining a frequency related parameter of a local frequency source within a receiver includes receiving, at an antenna of the receiver, a plurality of signals from a plurality of remote sources, generating motion compensated correlation results using a determined motion of the antenna of the receiver, the received plurality of signals, and a local signal derived from the local frequency source, using predictive control to predict the frequency related parameter of the local frequency source, phase compensating the motion compensated correlation results to produce phase compensated correlation results using a plurality of phasor sequences that are based on the predicted frequency related parameter of the local frequency source, and jointly analysing the phase compensated correlation results associated with the plurality of remote sources to determine a frequency model/offset for the local frequency source.

In some embodiments, the method can further include adjusting a frequency of the local frequency source based on at least one of the predicted frequency related parameter or the determined frequency offset.

In some embodiments, at least one of the plurality of remote sources includes a reference frequency and the frequency of the local frequency source is adjusted to coincide with the reference frequency.

In some embodiments, predictive control includes monitoring at least one of an environmental parameter of an environment in which the receiver is operating or an operating parameter of the receiver. In such embodiments, the environmental parameter includes at least one of a temperature of the environment in which the receiver is operating or a rate of change of the temperature of the environment in which the receiver is operating, and the operating parameter comprises a turning on or off of a component associated with the receiver.

In some embodiments, a frequency error related to the predicted frequency related parameter is determined using at least one of a machine learning model trained to determine a frequency error based on a change in at least one monitored parameter affecting the frequency of the local frequency source or a stored look up table that associates a frequency error with a change in at least one monitored parameter affecting the frequency of the local frequency source.

In some embodiments, an apparatus for determining a frequency related parameter of a frequency source within a receiver includes at least one processor and at least one memory for storing programs and instructions that, when executed by the at least one processor, configures the apparatus to receive, at an antenna of the receiver, a plurality of signals from a plurality of remote sources, generate motion compensated correlation results using a determined motion of the antenna of the receiver, the received plurality of signals, and a local signal derived from the local frequency source, use predictive control to predict the frequency related parameter of the local frequency source, phase compensate the motion compensated correlation results to produce phase compensated correlation results using a plurality of phasor sequences that are based on the predicted frequency related parameter of the local frequency source, and jointly analyze the phase compensated correlation results associated with the plurality of remote sources to determine a frequency offset of the local frequency source.

In some embodiments, a system for determining a frequency related parameter of a frequency source within a receiver includes a receiver including an antenna and a local frequency source, a plurality of remote sources of a plurality of signals, the plurality of signals including at least one reference frequency signal and an apparatus including at least one processor and at least one memory for storing programs and instructions. When the programs and instructions are executed by the at least one processor, the apparatus is configured to receive, at the antenna of the receiver, a plurality of signals from the plurality of remote sources, generate motion compensated correlation results using a determined motion of the antenna of the receiver, the received plurality of signals, and a local signal derived from the local frequency source, use predictive control to predict the frequency related parameter of the local frequency source, phase compensate the motion compensated correlation results to produce phase compensated correlation results using a plurality of phasor sequences that are based on the predicted frequency related parameter of the local frequency source, and jointly analyze the phase compensated correlation results associated with the plurality of remote sources to determine a frequency offset of the local frequency source.

In some embodiments the system further includes a frequency controller and the apparatus is further configured to adjust, using the frequency controller, a frequency of the local frequency source based on at least one of the predicted frequency related parameter or the determined frequency offset. In such embodiments, the frequency of the local frequency source can be adjusted to coincide with the at least one reference frequency signal.

In some embodiments, the system further includes at least one sensor and the predictive control includes monitoring, using the at least one sensor, at least one of an environmental parameter of an environment in which the receiver is operating or an operating parameter of the receiver. In such embodiments, the environmental parameter can include at least one of a temperature of the environment in which the receiver is operating or a rate of change of the temperature of the environment in which the receiver is operating, and the operating parameter comprises a turning on or off of a component associated with the receiver.

Other and different embodiments of the present principles are described below. For example, in some embodiments, there is provided a method for determining and correcting a frequency related parameter of a frequency source within a receiver including providing a local frequency using the frequency source of the receiver; receiving, at an antenna of the receiver, at least one signal from at least one remote source, the at least one signal including a respective remote reference frequency; monitoring at least one of a frequency of the frequency source of the receiver or at least one parameter affecting the frequency of the frequency source of the receiver; predicting respective frequency offsets indicative of a stability of the frequency source of the receiver based on detected changes of the at least one of the frequency of the frequency source of the receiver or the at least one parameter affecting the frequency of the frequency source of the receiver; correlating the local frequency with at least one respective remote reference frequency of the received at least one signal to generate at least one respective correlation result; determining a motion of the antenna of the receiver; using the determined antenna motion, performing motion compensated correlation on the received at least one signal to generate at least one motion compensated correlation result of the at least one signal; dividing the at least one motion compensated correlation result into subsets based on the determined stability of the frequency source; phase compensating each of the subsets of the at least one motion compensated correlation result to produce respective phase compensated correlation results using a plurality of phasor sequences for each of the subsets of the at least one motion compensated correlation result, which represent an error in a frequency of the local frequency source during each of the subsets; and applying a phase offset to the frequency source of the receiver, the phase offset being based on at least one of the determined stability of the frequency source of the receiver and the produced, respective phase compensated correlation results.

In some embodiments, in the method the at least one remote source includes two or more remote sources and the receiver receives at least one signal from each of the two or more remote sources and the method further comprises jointly analysing the phase compensated correlation results associated with the two or more remote sources to determine a frequency related parameter of the frequency source of the receiver.

In some embodiments, in the method the at least one parameter affecting the frequency of the frequency source of the receiver comprises at least one of an environmental parameter of an environment in which the receiver is operating or an operating parameter of the receiver.

In some embodiments, in the method the environmental parameter includes at least one of a temperature of the environment in which the receiver is operating or a rate of change of the temperature of the environment in which the receiver is operating, and the operating parameter comprises at least one of a determined movement of the receiver or a turning on or off of a component of the receiver.

In some embodiments, in the method applying a phase offset further includes determining a preferred estimated frequency offset for each subset based on a phasor sequence in each subset that produces a highest combined correlation.

In some embodiments, in the method preferred frequency offsets for each subset are concatenated to form a phasor sequence having a length of a desired coherent integration interval for the frequency of the local frequency of the frequency source of the receiver and at least one remote reference frequency of the received at least one signal.

In some embodiments, in the respective frequency offsets indicative of a stability of the frequency of the frequency source of the receiver are predicted using at least one of a machine learning model trained to determine a frequency offset based on a change in at least one of the monitored frequency or the at least one parameter affecting the frequency of the frequency source or a stored look up table that associates a frequency offset with a change in at least one of the monitored frequency or the at least one parameter affecting the frequency of the frequency source.

In some embodiments of the present principles, there is provided an apparatus for determining and correcting a frequency related parameter of a frequency source within a receiver including at least one processor and at least one memory for storing programs and instructions that, when executed by the at least one processor, configures the apparatus to provide a local frequency using the frequency source of the receiver; receive, at an antenna of the receiver, at least one signal from at least one remote source, the at least one signal including a respective remote reference frequency; monitor at least one of a frequency of the frequency source of the receiver or at least one parameter affecting the frequency of the frequency source of the receiver; predict respective frequency offsets indicative of a stability of the frequency source of the receiver based on detected changes of the at least one of the frequency of the frequency source of the receiver or the at least one parameter affecting the frequency of the frequency source of the receiver; correlate the local frequency with at least one respective remote reference frequency of the received at least one signal to generate at least one respective correlation result; determine a motion of the antenna of the receiver; using the determined antenna motion, perform motion compensated correlation on the received at least one signal to generate at least one motion compensated correlation result of the at least one signal; divide the at least one motion compensated correlation result into subsets based on the determined stability of the frequency source; phase compensate each of the subsets of the at least one motion compensated correlation result to produce respective phase compensated correlation results using a plurality of phasor sequences for each of the subsets of the at least one motion compensated correlation result, which represent an error in a frequency of the local frequency source during each of the subsets; and apply a phase offset to the frequency source of the receiver, the phase offset being based on at least one of the determined stability of the frequency source of the receiver and the produced, respective phase compensated correlation results.

In some embodiments of the present principles, there is provided a system for determining and correcting a frequency related parameter of a frequency source within a receiver including a receiver including an antenna and a frequency source; at least one sensor for sensing at least one of a frequency of the frequency source of the receiver or a parameter affecting a frequency of the frequency source of the receiver; at least one remote source of at least one signal including a respective reference frequency signal; and an apparatus including at least one processor and at least one memory for storing programs and instructions. In the apparatus when the programs and instructions are executed by the at least one processor, the apparatus is configured to provide a local frequency using the frequency source of the receiver; receive, at the antenna of the receiver, at least one signal from the at least one remote source, the at least one signal including a respective remote reference frequency; monitor, using the at least one sensor, at least one of a frequency of the frequency source of the receiver or at least one parameter affecting the frequency of the frequency source of the receiver; predict respective frequency offsets indicative of a stability of the frequency source of the receiver based on detected changes of the at least one of the frequency of the frequency source of the receiver or the at least one parameter affecting the frequency of the frequency source of the receiver; correlate the local frequency with at least one respective remote reference frequency of the received at least one signal to generate at least one respective correlation result; determine a motion of the antenna of the receiver; using the determined antenna motion, perform motion compensated correlation on the received at least one signal to generate at least one motion compensated correlation result of the at least one signal; divide the at least one motion compensated correlation result into subsets based on the determined stability of the frequency source; phase compensate each of the subsets of the at least one motion compensated correlation result to produce respective phase compensated correlation results using a plurality of phasor sequences for each of the subsets of the at least one motion compensated correlation result, which represent an error in a frequency of the local frequency source during each of the subsets; and apply a phase offset to the frequency source of the receiver, the phase offset being based on at least one of the determined stability of the frequency source of the receiver and the produced, respective phase compensated correlation results.

In some embodiments of the present principles, there is provided a method including providing a local frequency reference using a local oscillator; receiving at least one first signal at a receiver from at least one first remote source, along respective directions of arrival; determining a movement of the receiver in each of a plurality of sequential time periods; for each of the at least one first received signals: using the local frequency reference to provide a first local signal; providing a first correlation signal by correlating the first local signal with the first received signal; and providing a plurality of hypothesized frequency offsets and, for each of the plurality of hypothesized frequency offsets: providing phase compensation of at least one of the first local signal, the first received signal, and the first correlation signal based on the determined movement of the receiver along the respective direction of arrival to produce a phase compensated first correlation signal; determining a preferred frequency offset based on the plurality of hypothesized frequency offsets in each of the plurality of sequential time periods and the produced phase compensated first correlation signals to provide a vector comprising a plurality of unique frequency offsets in the local frequency reference in each of the plurality of sequential time periods; receiving a second signal at the receiver from a second remote source along a direction of arrival; using the local frequency reference to provide a second local signal; providing a second correlation signal by correlating the second local signal with the second signal; and providing phase compensation of at least one of the second local signal, the second received signal, and the second correlation signal based on the determined movement along the direction of arrival of the second received signal and the vector.

In some embodiments, the method can be performed in a positioning system, and the at least one first signal and the second signal can be positioning signals. In this way, different local oscillator corrections can be provided across an extended period, which is the sum of the plurality of sequential time periods. In one embodiment, the second local signal can be generated with different local oscillator corrections in each of the sequential time periods. This daisy-chained second local signal can then be correlated against the received second signal and can be phase compensated. Such techniques enable Supercorrelation™ processing (i.e. long coherent integration of signals) to be performed even when there is a relatively unstable local oscillator because each period of instability can be independently corrected. Such embodiments of the present principles advantageously improves the ability of a positioning system of the present principles to determine a range to a GNSS satellite in a poor signal environment when the system itself has a relatively poor local oscillator.

In some embodiments of the present principles, different oscillator corrections can instead be applied, using the vector, to the received second signal or the second correlation signal, or any combination of the second local signal, the second signal, and the second correlation signal. For example, the second signal, rather than the second local signal, can be adjusted using the vector. This effectively introduces the same or very similar variations that are present in the second local signal due to the relatively poor local oscillator into the second signal. This would improve the result of correlating the second signal (adjusted using the vector) and the (unadjusted) second local signal because similar variations would be then present in each signal.

Calculating the vector of unique frequency offsets involves providing a plurality of hypothesized frequency offsets and providing phase compensation of at least one of the first local signal, the at least one first signal, and the first correlation signal based on the determined movement in the respective direction of arrival for the plurality of hypothesized frequency offsets, and determining a preferred frequency offset based on the plurality of hypothesized frequency offsets in each of the plurality of sequential time periods and the produced phase compensated first correlation signals. Embodiments of the present principles search for the frequency offset that can provide the best correlation results. This corresponds to a search in frequency space. Alternatively or in addition, in some embodiments there can be a two-dimensional search across frequency and rate of change of frequency to find the combination of variables that provide the best correlation results (e.g. the highest peak for the correlation signal), and reveals the best solution for the local oscillator frequency related errors.

The frequency offset can be determined relative to another frequency reference that is a close approximation to a “true” frequency reference, which can be derived from a well-modelled, high fidelity atomic oscillator. The frequency offset can therefore be determined with respect to a “known or predictable frequency” that is generated using a much more accurate oscillator than the local oscillator.

In some embodiments, the local signals can be replicas of a pseudorandom number sequence from a GNSS satellite. The second local signal can be generated based on the frequency reference from the local oscillator together with the plurality of unique frequency offsets, which correspond to the determined error in the local oscillator frequency reference across sequential time periods. This can create a second local signal in which local oscillator error is substantially removed, and this can significantly enhance positioning accuracy.

In some embodiments of the present principles, phase compensation can be applied using techniques known in the art. For example, the phase compensation can be applied to only one of, or more than one of: the second signal, the second local signal, or the second correlation signal resulting from correlating the second signal and the second local signal. Similarly, phase compensation can be applied to any of the at least one first signal, the first local signal and the resulting first correlation signal. The correlation step can be performed using known correlation techniques in GNSS (Global Navigation Satellite Systems) or other positioning systems.

In some embodiments, the process of determining a movement of the receiver in each of the plurality of sequential time periods can include determining a component of motion of the receiver along a line of sight to each respective remote source, which can be a positioning source or any other type of source. The local frequency reference can be a timing signal of various possible forms, such as a sine wave or a square wave.

Embodiments of the present principles can include providing a plurality of hypothesized frequency rate offsets; wherein the step of providing phase compensation for each of the plurality of hypothesized frequency offsets comprises providing phase compensation for each of the plurality of hypothesized frequency and frequency rate offsets; and wherein the step of determining the preferred frequency offset based on the plurality of hypothesized frequency offsets in each of the plurality of sequential time periods comprises determining the preferred frequency offset and a preferred frequency rate offset in each of the plurality of sequential time periods to provide the vector comprising the plurality of unique frequency offsets and a plurality of unique frequency rate offsets in the local frequency reference in each of the plurality of sequential time periods. As described previously, in some embodiments the frequency rate corrections can be applied, using the vector, to any of the second local signal, the second signal or the second correlation signal, or any combination of the second local signal, the second signal, and the second correlation signal. As such, a local oscillator of the present principles can be corrected in terms of its frequency and its rate of change of frequency. In some embodiments, it would be possible to provide higher order corrections as well. However, it has been found that sufficiently accurate corrections can be provided using only frequency and frequency rate offsets, which minimizes computational loads.

In some embodiments, providing phase compensation for each of the plurality of hypothesized frequency and frequency rate offsets includes providing phase compensation for each of a plurality of pairs of the hypothesized frequency and frequency rate offsets. As such, phase compensated first correlation signals can be produced for each combination of frequency and frequency rate. This enables the optimal combination of frequency and frequency rate to be determined in each of the plurality of sequential time periods so that the evolving error in the local oscillator can be mapped more precisely.

In some embodiments, receiving at least one first signal comprises receiving a plurality of first signals at the receiver from a plurality of first remote sources, wherein determining the preferred frequency offset based on the plurality of hypothesized frequency offsets in each of the plurality of sequential time periods and the phase compensated first correlation signal is performed based on a plurality of phase compensated first correlation signals. As such, the preferred frequency offset is determined based on a plurality of received first signals, which avoids one issue that can arise in some scenarios when using only one first signal from a single first remote source.

For example, one such scenario can arise when the first signal is received along a direct line of sight and, at the same time, along an indirect direction of arrival resulting from a reflection having an increased path length from the remote source to the receiver. In such a scenario, there can be two hypothesized frequency offsets that appear to produce a better phase compensated first correlation signal. However, only one of the hypothesized frequency offsets corresponds to an error in the local oscillator. The remaining hypothesized frequency offset can correspond to the reflected first signal. If the preferred frequency offset is selected (or otherwise determined) based on the hypothesis corresponding to the reflected signal, then the preferred frequency offset would represent a phase offset caused by the increased path difference of the reflected signal. In this scenario, the preferred frequency offset does not represent the error in the local oscillator in a given time period. This means that preferred frequency offset in general cannot be used to apply a correction in the processing of other received signals (such as the second signal) to achieve better phase compensated correlation results. In some embodiments, using a plurality of first signals avoids this issue because, for a given time period, each of the received first signals has a common hypothesized frequency offset that produces a better phase compensated first correlation signal. The common hypothesized frequency offset corresponds to the error in the local frequency reference produced by an unstable local oscillator. Therefore, determining the preferred frequency offset in each sequential time period based on a plurality of first signals enables the hypothesized frequency offset corresponding to the error in the local oscillator to be recognized through a comparison of the phase compensated first correlation signals.

In some embodiments, determining the preferred frequency offset based on the plurality of phase compensated first correlation signals can be performed by, for each hypothesized frequency offset, combining the phase compensated first correlation signals produced for each of the plurality of received first signals and determining the hypothesized frequency offset corresponding to the highest combined correlation. As such, the hypothesized frequency offset corresponding to the error in the local frequency reference produced by the unstable local oscillator can be identified. In some embodiments, the combination can be a sum or a multiplication.

In some embodiments, a suitable cost function can be used to determine the frequency and/or frequency rate corresponding to the highest combined correlation. A process of the present principles can include determining one or more operating conditions in a system in each of the plurality of sequential time periods and determining an initial estimated frequency offset in the local frequency reference based on the one or more operating conditions. In such embodiments, an initial estimated frequency offset can be a rough prediction or estimate of the error in the local oscillator in a given time period of the sequential time periods. As such, the initial estimated frequency offset can be used as a starting point or initial condition when calculating the offset more precisely using the plurality of hypothesized frequency offsets, which enables the vector to be produced more efficiently.

In various embodiments of the present principles, the determination of the initial estimated frequency offset can be performed in a variety of ways. In one example, a lookup table can be used to retrieve frequency offsets calculated previously in the same or similar operating conditions. In another example, a model configured to predict a frequency offset in the local oscillator based on the operating conditions of the system can take the determined one or more operating conditions as an input. The model can then output a frequency prediction based on the one or more operating conditions. Using a model in accordance with the present principles can also be referred to as “predictive control”. In some embodiments, the model can be a neural network or machine learning model or algorithm, a formula, or any other suitable kind of model. The model can be pre-trained and/or can be retrained continuously based on calculations of preferred frequency offsets and respective, corresponding determined operating conditions. Embodiments of the present principles can further include a step of retraining the model based on the one or more determined operating conditions and a preferred frequency offset. In a further embodiment, the lookup table can provide an input to the model.

In some embodiments, the one or more determined operating conditions include one or more of temperature, a rate of change of temperature, an operating state, or a determined movement of a component in the system. The one or more operating conditions can be determined using a sensor that measures a physical variable that enables a relevant parameter such as a temperature to be calculated. Alternatively or in addition, in the case of the one or more operating conditions including an operating state of a component, a determination of whether a component is turned on or off can be performed using control logic without a sensor.

In some embodiments, a process of the present principles can include providing the preferred frequency offset in each of the plurality of sequential time periods and the one or more determined operating conditions to a stored dataset. As such, the behavior of the local oscillator in particular operating conditions can be tracked for future reference.

In some embodiments, the determined operating conditions can include temperature and whether the temperature is increasing or decreasing. This is because oscillators can exhibit temperature hysteresis, i.e., can behave differently at a given temperature depending on the recent or historical temperature of the oscillator. In one example, each temperature value can have two corresponding frequency offset entries in the stored data set. One offset entry can correspond to when the oscillator is at the respective temperature and the temperature is increasing and the other offset entry can correspond to the same temperature but when the temperature is decreasing. As such, the stored data set can be configured to account for temperature hysteresis effects in the local oscillator. Similarly, in some embodiments, two entries for frequency rate (or any other phase or frequency correction term) can be stored for each temperature. In one example, a large number of potential operating conditions can be measured in order to update a multi-dimensional lookup table.

In some embodiments, an initial estimated frequency offset from a stored dataset or an initial model can provide initial conditions when calculating the vector of unique frequency offsets in the local frequency reference in the plurality of sequential time periods. Specifically, the values in the stored dataset or output from the model can be used as seed values or initial values and can also define a search window. Such a technique of the present principles has a dual benefit by increasing the likelihood that the seed values are close to the true values, and by decreasing the processing power required to search across all possible frequency offset values. In one example, the “seed value” is the first point within a search space to be tested within a search window of the test space. The search window can be set to a particular narrower width based on the values in the stored dataset or produced from the model. For example, in some embodiments, the width of a search window for frequency or frequency rate values can be set based on a percentage of a previously calculated frequency or frequency rate value.

Alternatively, in some embodiments the narrower search window can have a fixed width that is centered on a previously calculated value. A wider search window can be set if the dataset contains no previously calculated value for the corresponding operating condition or conditions, wherein the wider search window is wider than the narrower search window.

In some embodiments, the at least one first signal can be less attenuated than the second signal. In one example, the respective directions of arrival of the at least one first signal may be more favorable lines of sight to the receiver compared to the direction of arrival of the second signal, such that the at least one first signal can be received with a better signal to noise ratio than the second signal. As such, the more favorable at least one first signals are used to determine a frequency offset that can be used in turn to correct the second local signal, thus enabling correlation with the less favorable second signal over an extended period. The at least one first signal can be integrated coherently over the instability period of the local oscillator.

In some embodiments, a duration of one or more of the plurality of sequential time periods is determined based on the one or more determined operating conditions of the system. In some embodiments, at least two of the plurality of sequential time periods have different durations with respect to one another. As such, the vector can account for the evolving behavior of the local oscillator more effectively. In some embodiments, longer time periods can be used if the operating parameter of the positioning system is indicative of relatively benign conditions for the local oscillator. On the other hand, if the operating conditions are extreme, then the time periods can be shorter.

In some embodiments, extreme operating conditions can include high or low temperatures, sudden temperature changes, vibrations or sudden movements, or the use of particular applications or hardware. It has been found that these operating conditions can adversely affect the stability of the local oscillator, and therefore counter action can be desirable, such as the use of shorter time periods.

In some embodiments, absent the detection of any external operating parameter the individual length of each of the sequential time periods can be stored in memory by default in the device. In some embodiments the default length of each individual time period can be approximately 0.1 seconds, 0.2 seconds, 0.5 seconds, 1 second or 2 seconds. The duration and number of sequential time periods can be selected in order to minimize the number of offset calculations required while still providing sufficient oscillator corrections. As calculating each offset in the local oscillator can be computationally intensive, this creates a faster and more efficient calculation of the vector.

In some embodiments, each of the plurality of sequential time periods corresponds to a duration over which the local oscillator is calculated or assumed to provide a stable frequency reference. As such, frequency offsets calculated for each of the sequential time periods can be an accurate offset across each individual time period. Alternatively, each of the plurality of sequential time periods may not correspond to a duration over which the local oscillator is calculated or assumed to be stable. For example, each of the sequential time periods can be longer than an assumed or calculated period of stability, and interpolation can be applied between calculated values.

In some embodiments, the combined duration of the plurality of sequential time periods can be at least equal to an integration period over which the second local signal and the received second signal are correlated during the step of providing the second correlation signal. As such, the vector can store the frequency offsets in the local oscillator across the full integration period in order to map the evolving error in the local oscillator for the full integration period. The vector can be combined with the local frequency reference to generate a second local signal that is corrected across the whole integration period to enable a coherent integration to be performed for longer than the instability period of the local oscillator. In some examples, the integration period may be 0.5 seconds or longer, such as, 1 second, 2 seconds, 3 seconds, or longer.

In some embodiments it can be possible to interpolate corrections between time periods and thus, it may be possible to increase the number of sequential time periods or to decrease the number of measurements of frequency offset so that interpolation can be used between measurement points. However, this approach requires that the sampling rate is high enough to correctly characterize trends in the frequency and frequency rate offsets. In some embodiments, determining a preferred frequency offset based on the plurality of hypothesized frequency offsets includes interpolating a preferred frequency offset between two or more of the plurality of hypothesized frequency offsets. As such, a greater number of frequency correction terms can be obtained using a process that is less computationally intensive than calculating the frequency offsets directly. The interpolation can be applied retroactively after calculating frequency offsets corresponding to some or all of the plurality of sequential time periods. Additionally, interpolation may be applied after determining that the frequency offsets vary gradually, smoothly and/or predictably across some or all of the sequential time periods. The interpolation can be performed in response to determining that the operating conditions meet a threshold. In some embodiments, the threshold can be a set of one or more criteria that indicates the operating conditions are relatively favorable for the local oscillator (i.e. the environment of the local oscillator is favorable for enabling good oscillator stability). Equivalently, if it is found that frequency offsets vary predictably, the duration of the time periods within the plurality of sequential time periods can be increased.

Alternatively or in addition, in some embodiments determining a preferred frequency offset based on the plurality of hypothesized frequency offsets can comprise selecting one of the hypothesized frequency offsets, which can correspond to the highest or best of the produced phase compensated first correlation signals. In some embodiments, selecting one of the hypothesized offsets can provide a sufficient offset of the frequency.

In some embodiments of the present principles, after providing a vector comprising a plurality of unique frequency offsets in the local frequency reference in each of the plurality of sequential time periods, a method of the present principles can include determining an additional frequency offset and adjusting the vector based on the determined additional frequency offset. In one example, this can be accomplished by, for each of the at least one first received signals: using the local frequency reference to provide a third local signal; providing third correlation signals by correlating the third local signal with each of the one or more received first signals; providing a further plurality of hypothesized frequency offsets and, for each of the further plurality of hypothesized frequency offsets, providing phase compensation of at least one of the third local signal, the one or more received first signals, and the third correlation signals based on the vector and the determined movement of the receiver along the respective direction of arrival to produce phase compensated third correlation signals; and determining a frequency correction based on the further plurality of hypothesized frequency offsets and the produced phase compensated third correlation signals; and adding the determined frequency correction to the vector in each of the plurality of sequential time periods. As such, a method of the present principles can correct for an overarching frequency error that is present across several of the sequential time periods. This improves the ability of the vector to correct any of the second local signal, the second signal or the second correlation signal, or any combination thereof.

Embodiments of the present principles can further include calculating, based on the second correlation signal, a range or a pseudo-range of the receiver to the second remote source. The range or pseudo-range can be combined with a plurality of other ranges or pseudo-ranges obtained from a plurality of remote sources to determine a position.

Embodiments of the present principles can be performed at least partially in a positioning device, such as a mobile device, comprising a 5G modem, wherein the local oscillator is provided in the positioning device.

In some embodiments of the present principles, a method for determining a frequency related parameter of a frequency source within a receiver includes receiving a plurality of signals from a plurality of remote sources; generating motion compensated correlation results using a determined receiver motion, the received signals and a local signal derived from the local frequency source; phase compensating the motion compensated correlation results to produce phase compensated correlation results using a plurality of phasor sequences that represent frequency error of the local frequency source; and jointly analyzing the phase compensated correlation results associated with the plurality of remote sources to determine a frequency related parameter of the local frequency source.

In some embodiments, an apparatus for performing signal correlation within a signal processing system includes at least one processor and at least one non-transient computer readable medium for storing instructions that, when executed by the at least one processor, causes the apparatus to perform operations including: receiving a plurality of signals from a plurality of remote sources; generating motion compensated correlation results sing a determined receiver motion, the received signals and a local signal derived from the local frequency source; phase compensating the motion compensated correlation results to produce phase compensated correlation results using a plurality of phasor sequences that represent frequency error of the local frequency source; and jointly analyzing the phase compensated correlation results associated with the plurality of remote sources to determine a frequency related parameter of the local frequency source.

In some embodiments, a method, which may be performed in a positioning system, includes providing a local frequency reference using a local oscillator; receiving at least one signal, at a receiver, from at least one remote source, along respective directions of arrival; determining a movement of the receiver; determining one or more operating conditions in a system performing the method; determining an initial estimated frequency offset in the local frequency reference based on the one or more operating conditions; for each of the at least one received signals: using the local frequency reference to provide a local signal; providing a correlation signal by correlating the local signal with the received signal; and providing phase compensation of at least one of the local signal, the at least one received signal, and the correlation signal based on the determined movement of the receiver along the respective direction of arrival to produce a phase compensated correlation signal; dynamically adjusting, based on the phase compensated correlation signals and the initial estimated frequency offset, a frequency offset value to determine a preferred estimated value for the frequency offset in the local frequency reference.

In such embodiments, the initial estimated frequency offset can be used as a starting point or initial condition when determining the preferred frequency offset, which corresponds to a more precise determination of the offset in the local oscillator calculated using the at least one signal. This enables the preferred estimated value to be determined more efficiently. In some embodiments, the determination of the initial estimated frequency offset can be performed in a variety of ways. In some embodiments, the initial estimated frequency can be determined by comparing the one or more determined operating conditions to a frequency offset calculated previously for the same or similar operating conditions. In one example, this comparison can be performed using a stored data set from which frequency offsets calculated previously in the same or similar operating conditions can be retrieved. In another example, the comparison can be performed using a model configured to predict a frequency offset in the local oscillator based on the determined operating conditions of the system. The model can take the determined one or more operating conditions as an input and output a frequency prediction or estimation. In some embodiments, the model can be a neural network or machine learning model or algorithm, a formula, or any other suitable kind of model. Applying a model in this manner in accordance with the present principles can be referred to as “predictive control”. The model can be pre-trained and/or can be re-trained continuously based on calculations of frequency offsets and their corresponding determined operating conditions. Alternatively or in addition, a lookup table can provide an input to the model, or could be used to continuously retrain the model as the lookup table is updated.

In some embodiments of the present principles, one or more operating conditions can be determined using a sensor that measures a physical variable that enables a relevant parameter, such as temperature, to be calculated. Alternatively or in addition, in the case of the one or more operating conditions including an operating state of a component, a determination of whether a component is turned on or off can be performed using control logic without a sensor. For example, in some embodiments, the one or more operating conditions include one or more of temperature, a rate of change of temperature, an operating state, a determined movement, or an indication of whether a component in the system is turned on or off. In such embodiments, the one or more operating conditions can represent a more complete characterization of the conditions affecting the local oscillator.

In some embodiments, the determined operating conditions in the system include can also include whether the temperature is increasing or decreasing. This is because oscillators can exhibit temperature hysteresis (i.e., can behave differently at a given temperature depending on the recent or historical temperature of the oscillator). In one example, each temperature value can have two corresponding frequency offsets in the stored data set. One offset entry can correspond to a situation in which the oscillator is at a respective temperature and the temperature is increasing and the other offset entry can correspond to a same temperature but in an instance during which the temperature is decreasing. As such, the stored data set can be configured to account for temperature hysteresis effects in the local oscillator. Similarly, two entries for frequency rate (or any other phase or frequency correction term) can be stored for each temperature.

Alternatively or in addition, other measured operating conditions can include a rate of change of temperature, data from inertial sensors, information on other processing operations that are being performed in the device or other applications that are in use, whether the screen of the device is on, and many other factors. In this way, a multi-dimensional lookup table can be generated that is indicative of frequency offsets that have been observed historically in different operating conditions. A look up table of the present principles is of great utility because of the high likelihood of repeatability of measurements. Thus, an observed frequency offset is likely to be close to a frequency offset that was observed previously during similar operating conditions.

In some embodiments, a lookup table of the present principles can include a list of operating condition measurements or determinations and corresponding preferred frequency offsets produced under the measured operating conditions. In some embodiments, temperature can be measured using a thermistor, a thermocouple or any other suitable sensor.

Embodiments of the present principles can include taking a remedial action based on the determined one or more operating conditions to mitigate an operating condition negatively affecting the stability of the local oscillator. For example, the remedial action can include one or more of reducing the power consumption of a component or turning off a component of, for example, a receiver of the present principles. Any suitable remedial action can be implemented.

Embodiments of the present principles can further include the step of, at a later time, determining one or more subsequent operating conditions of, for example a receiver of the present principles, and supplying a frequency rate offset from a stored dataset corresponding to the one or more subsequent operating conditions, as an initial estimated frequency rate offset for dynamically adjusting a frequency rate offset value to determine a preferred estimated value for the frequency rate offset in the local frequency source. In such embodiments, previous calculations of frequency rate offsets can also be stored and provided later to provide accurate seed values for determining preferred frequency rate offsets in accordance with the present principles.

In some embodiments, a model of the present principles can be pre-trained and/or can be re-trained continuously based on calculations of frequency offsets and their corresponding determined operating conditions. In such embodiments, the model can be updated based on the preferred frequency offset value and the determined one or more operating conditions. The model can also be used to predict the frequency rate offset, or any other higher order correction terms in addition to the frequency offset.

In some embodiments, a search window for a preferred estimated value for the frequency offset can be defined based on the initial estimated frequency offset. Equally, a search window for a preferred estimated value of a frequency rate offset can be defined based on an estimated frequency rate offset. In a process of searching for the estimated value for the frequency offset, a number of candidate values can be ‘tested’, and the best-fit value can be selected. The process of testing candidate values is computationally intensive, and therefore it is advantageous to reduce the task as much as possible. By using the estimated frequency offset in accordance with the present principles, which could be supplied from the stored dataset or output from the model, it is possible to start the searching process in confidence that the initial value is already quite close to the expected true value.

In some embodiments, the search window can be defined based on fixed values that are greater than and less than the initial estimated value. In some embodiments, the search window can be defined based on, for example as a percentage value of, estimated frequency offset values in the stored dataset or produced from the model. In one example in which the stored frequency offset values are based on averages, the search window can be defined based on a certain number of standard deviations away from the average. This can helpfully focus the search space on the most likely frequency offset values, reducing computational load by avoiding calculations related to frequency offset values that are statistically unlikely to occur, based on the previous measurements.

In some embodiments, a search window for the preferred estimated value for the frequency rate offset can be defined, based on the initial estimated frequency rate offset. In this way, there can be a two-dimensional search window across frequency and rate of change of frequency. Reducing the size of this search window is highly advantageous in improving computational efficiency.

Those skilled in the art will also appreciate that, while various items are illustrated as being stored in memory or on storage while being used, these items or portions of them can be transferred between memory and other storage devices for purposes of memory management and data integrity. Alternatively, in other embodiments some or all of the software components can execute in memory on another device and communicate with a computing device via inter-computer communication. Some or all of the system components or data structures can also be stored (e.g., as instructions or structured data) on a computer-accessible medium or a portable article to be read by an appropriate drive, various examples of which are described above. In some embodiments, instructions stored on a computer-accessible medium separate from the computing device can be transmitted to the computing device via transmission media or signals such as electrical, electromagnetic, or digital signals, conveyed via a communication medium such as a network and/or a wireless link. Various embodiments can further include receiving, sending or storing instructions and/or data implemented in accordance with the foregoing description upon a computer-accessible medium or via a communication medium. In general, a computer-accessible medium can include a storage medium or memory medium such as magnetic or optical media, e.g., disk or DVD/CD-ROM, volatile or non-volatile media such as RAM (e.g., SDRAM, DDR, RDRAM, SRAM, and the like), ROM, and the like.

The methods and processes described herein may be implemented in software, hardware, or a combination thereof, in different embodiments. In addition, the order of methods can be changed, and various elements can be added, reordered, combined, omitted or otherwise modified. All examples described herein are presented in a non-limiting manner. Various modifications and changes can be made as would be obvious to a person skilled in the art having benefit of this disclosure. Realizations in accordance with embodiments have been described in the context of particular embodiments. These embodiments are meant to be illustrative and not limiting. Many variations, modifications, additions, and improvements are possible. Accordingly, plural instances can be provided for components described herein as a single instance. Boundaries between various components, operations and data stores are somewhat arbitrary, and particular operations are illustrated in the context of specific illustrative configurations. Other allocations of functionality are envisioned and can fall within the scope of claims that follow. Structures and functionality presented as discrete components in the example configurations can be implemented as a combined structure or component. These and other variations, modifications, additions, and improvements can fall within the scope of embodiments as defined in the claims that follow.

In the foregoing description, numerous specific details, examples, and scenarios are set forth in order to provide a more thorough understanding of the present disclosure. It will be appreciated, however, that embodiments of the disclosure can be practiced without such specific details. Further, such examples and scenarios are provided for illustration, and are not intended to limit the disclosure in any way. Those of ordinary skill in the art, with the included descriptions, should be able to implement appropriate functionality without undue experimentation.

References in the specification to “an embodiment,” etc., indicate that the embodiment described can include a particular feature, structure, or characteristic, but every embodiment may not necessarily include the particular feature, structure, or characteristic. Such phrases are not necessarily referring to the same embodiment. Further, when a particular feature, structure, or characteristic is described in connection with an embodiment, it is believed to be within the knowledge of one skilled in the art to affect such feature, structure, or characteristic in connection with other embodiments whether or not explicitly indicated.

Embodiments in accordance with the disclosure can be implemented in hardware, firmware, software, or any combination thereof. Embodiments can also be implemented as instructions stored using one or more machine-readable media, which may be read and executed by one or more processors. A machine-readable medium can include any mechanism for storing or transmitting information in a form readable by a machine (e.g., a computing device or a “virtual machine” running on one or more computing devices). For example, a machine-readable medium can include any suitable form of volatile or non-volatile memory.

In addition, the various operations, processes, and methods disclosed herein can be embodied in a machine-readable medium and/or a machine accessible medium/storage device compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium/storage device.

Modules, data structures, and the like defined herein are defined as such for ease of discussion and are not intended to imply that any specific implementation details are required. For example, any of the described modules and/or data structures can be combined or divided into sub-modules, sub-processes or other units of computer code or data as can be required by a particular design or implementation.

In the drawings, specific arrangements or orderings of schematic elements can be shown for ease of description. However, the specific ordering or arrangement of such elements is not meant to imply that a particular order or sequence of processing, or separation of processes, is required in all embodiments. In general, schematic elements used to represent instruction blocks or modules can be implemented using any suitable form of machine-readable instruction, and each such instruction can be implemented using any suitable programming language, library, application-programming interface (API), and/or other software development tools or frameworks. Similarly, schematic elements used to represent data or information can be implemented using any suitable electronic arrangement or data structure. Further, some connections, relationships or associations between elements can be simplified or not shown in the drawings so as not to obscure the disclosure.

This disclosure is to be considered as exemplary and not restrictive in character, and all changes and modifications that come within the guidelines of the disclosure are desired to be protected.

Any block, step, module, or otherwise described herein may represent one or more instructions which can be stored on non-transitory computer readable media as software and/or performed by hardware. Any such block, module, step, or otherwise can be performed by various software and/or hardware combinations in a manner which may be automated, including the use of specialized hardware designed to achieve such a purpose. As above, any number of blocks, steps, or modules may be performed in any order or not at all, including substantially simultaneously, i.e., within tolerances of the systems executing the block, step, or module.

Where conditional language is used, including, but not limited to, “can,” “could,” “may” or “might,” it should be understood that the associated features or elements are not required. As such, where conditional language is used, the elements and/or features should be understood as being optionally present in at least some examples, and not necessarily conditioned upon anything, unless otherwise specified.

Where lists are enumerated in the alternative or conjunctive (e.g., one or more of A, B, and/or C), unless stated otherwise, it is understood to include one or more of each element, including any one or more combinations of any number of the enumerated elements (e.g. A, AB, AC, ABC, ABB, etc.). When “and/or” is used, it should be understood that the elements may be joined in the alternative or conjunctive.

While the foregoing is directed to embodiments of the present principles, other and further embodiments of the present principles may be devised without departing from the basic scope thereof, and the scope thereof is determined by the claims that follow.

1. A method for determining a frequency related parameter of a local frequency source within a receiver, comprising:
receiving, at an antenna of the receiver, a plurality of signals from a plurality of remote sources;
generating motion compensated correlation results using a determined motion of the antenna of the receiver, the received plurality of signals, and a local signal derived from the local frequency source;
using predictive control to predict the frequency related parameter of the local frequency source;
phase compensating the motion compensated correlation results to produce phase compensated correlation results using a plurality of phasor sequences that are based on the predicted frequency related parameter of the local frequency source; and
jointly analysing the phase compensated correlation results associated with the plurality of remote sources to determine a frequency model for the local frequency source.

2. The method of claim 1, further comprising:
adjusting a frequency of the local frequency source based on at least one of the predicted frequency related parameter or the determined frequency model.

3. The method of claim 2, wherein at least one of the plurality of remote sources comprises a reference frequency and the frequency of the local frequency source is adjusted to coincide with the reference frequency.

4. The method of claim 1, wherein predictive control comprises monitoring at least one of an environmental parameter of an environment in which the receiver is operating or an operating parameter of the receiver.

5. The method of claim 4, wherein the environmental parameter comprises at least one of a temperature of the environment in which the receiver is operating or a rate of change of the temperature of the environment in which the receiver is operating, and the operating parameter comprises a turning on or off of a component associated with the receiver.

6. The method of claim 1, wherein a frequency error related to the predicted frequency related parameter is determined using at least one of a machine learning model trained to determine a frequency error based on a change in at least one monitored parameter affecting the frequency of the local frequency source or a stored look up table that associates a frequency error with a change in at least one monitored parameter affecting the frequency of the local frequency source.

7. The method of claim 1, wherein the frequency model comprises a frequency offset between a frequency of the local frequency source and a reference frequency of at least one of the signals from the plurality of the remote sources.

8. An apparatus for determining a frequency related parameter of a frequency source within a receiver, comprising:
at least one processor and at least one memory for storing programs and instructions that, when executed by the at least one processor, configures the apparatus to:
receive, at an antenna of the receiver, a plurality of signals from a plurality of remote sources;
generate motion compensated correlation results using a determined motion of the antenna of the receiver, the received plurality of signals, and a local signal derived from the local frequency source;
use predictive control to predict the frequency related parameter of the local frequency source;
phase compensate the motion compensated correlation results to produce phase compensated correlation results using a plurality of phasor sequences that are based on the predicted frequency related parameter of the local frequency source; and
jointly analyze the phase compensated correlation results associated with the plurality of remote sources to determine a frequency model for the local frequency source.

9. The apparatus of claim 8, wherein the apparatus is further configured to:
adjust a frequency of the local frequency source based on at least one of the predicted frequency related parameter or the determined frequency offset.

10. The apparatus of claim 9, wherein at least one of the plurality of remote sources comprises a reference frequency and the frequency of the local frequency source is adjusted to coincide with the reference frequency.

11. The apparatus of claim 8, wherein predictive control comprises monitoring at least one of an environmental parameter of an environment in which the receiver is operating or an operating parameter of the receiver.

12. The apparatus of claim 11, wherein the environmental parameter comprises at least one of a temperature of the environment in which the receiver is operating or a rate of change of the temperature of the environment in which the receiver is operating, and the operating parameter comprises a turning on or off of a component associated with the receiver.

13. The apparatus of claim 8, wherein a frequency error related to the predicted frequency related parameter is determined using at least one of a machine learning model trained to determine a frequency error based on a change in at least one monitored parameter affecting the frequency of the local frequency source or a stored look up table that associates a frequency error with a change in at least one monitored parameter affecting the frequency of the local frequency source.

14. The apparatus of claim 8, wherein the frequency model comprises at least a frequency offset between a frequency of the local frequency source and a reference frequency of at least one of the signals from the plurality of the remote sources.

15. A system for determining a frequency related parameter of a frequency source within a receiver, comprising:
a receiver including an antenna and a local frequency source;
at plurality of remote sources of a plurality of signals, the plurality of signals including at least one reference frequency signal;
an apparatus including at least one processor and at least one memory for storing programs and instructions that, when executed by the at least one processor, configures the apparatus to:
receive, at the antenna of the receiver, a plurality of signals from the plurality of remote sources;
generate motion compensated correlation results using a determined motion of the antenna of the receiver, the received plurality of signals, and a local signal derived from the local frequency source;
use predictive control to predict the frequency related parameter of the local frequency source;
phase compensate the motion compensated correlation results to produce phase compensated correlation results using a plurality of phasor sequences that are based on the predicted frequency related parameter of the local frequency source; and
jointly analyze the phase compensated correlation results associated with the plurality of remote sources to determine a frequency offset of the local frequency source.

16. The system of claim 15, wherein the system further comprises a frequency controller and the apparatus is further configured to:
adjust, using the frequency controller, a frequency of the local frequency source based on at least one of the predicted frequency related parameter or the determined frequency offset.

17. The system of claim 16, wherein the frequency of the local frequency source is adjusted to coincide with the at least one reference frequency signal.

18. The system of claim 15, wherein the system further comprises at least one sensor and the predictive control comprises monitoring, using the at least one sensor, at least one of an environmental parameter of an environment in which the receiver is operating or an operating parameter of the receiver.

19. The system of claim 18, wherein the environmental parameter comprises at least one of a temperature of the environment in which the receiver is operating or a rate of change of the temperature of the environment in which the receiver is operating, and the operating parameter comprises a turning on or off of a component associated with the receiver.

20. The system of claim 14, wherein a frequency error related to the predicted frequency related parameter is determined using at least one of a machine learning model trained to determine a frequency error based on a change in at least one monitored parameter affecting the frequency of the local frequency source or a stored look up table that associates a frequency error with a change in at least one monitored parameter affecting the frequency of the local frequency source.
